(19) United States
(12) Patent Application Publication
(10) Pub. No.: US 2025/0167073 A1
(43) Pub. Date: May 22, 2025

(54) POWER SEMICONDUCTOR DEVICE AND METHOD OF MANUFACTURING POWER SEMICONDUCTOR DEVICE

(71) Applicant: Mitsubishi Electric Corporation, Tokyo (JP)

(72) Inventors: Yasuyuki SANDA, Tokyo (JP); Tatsushi MORISADA, Tokyo (JP); Masaki GOTO, Tokyo (JP)

(73) Assignee: Mitsubishi Electric Corporation, Tokyo (JP)

(21) Appl. No.: 18/880,361

(22) PCT Filed: Oct. 13, 2022
(86) PCT No.: PCT/JP2022/038210

§ 371 Date: Dec. 31, 2024

(51) Int. Cl. H01L 23/40; H01L 23/367

(52) U.S. Cl. CPC H01L 23/4006; H01L 23/3677; H01L 2023/4031

(57) ABSTRACT

A power semiconductor device includes: heat sink integrated power modules each including a power module and a heat sink integrated with each other; a box-shaped holding portion including one surface having a plurality of openings formed thereon; and a structural support provided inside the holding portion and supporting the one surface. Heat dissipation fins of each of the heat sink integrated power modules are inserted in the holding portion from a corresponding one of the openings, and a heat sink base includes an outer peripheral edge supported on an adjacent region of the one surface, the adjacent region being adjacent to the corresponding opening. The structural support is disposed at a position corresponding to the space between the heat sink bases of the heat sink integrated power modules adjacent to each other.

### FIELD

The present disclosure relates to a power semiconductor device equipped with a heat sink and a power module, and a method of manufacturing the power semiconductor device.

### BACKGROUND

Patent Literature 1 describes a heat dissipation apparatus in which a plurality of modular cooling devices is inserted into an opening of a housing and held by the housing, the modular cooling devices each including a heat dissipation plate on which a heating element is disposed.

### CITATION LIST

### Patent Literature

Patent Literature 1: Japanese Patent No. 6448732

### SUMMARY OF INVENTION

### Problem to be Solved by the Invention

However, in a case where the structure of the heat dissipation apparatus described in Patent Literature 1 is applied to fix a plurality of power modules and a plurality of heat sinks by one housing, the housing may be bent by the weight of the power modules and the heat sinks. When the housing is bent, a gap is formed between the heat sink and the housing to reduce the air volume through heat dissipation fins in the heat sink, and the heat dissipation performance of the heat sink may be reduced. Moreover, when the housing is bent, the heat sink may not be properly fixed to the housing. If the heat sink cannot be properly fixed to the housing, a product cannot have sufficient vibration resistance.

The present disclosure has been made in view of the above, and an object thereof is to provide a power semiconductor device capable of preventing bending of a holding portion to which a plurality of power modules and heat sinks are attached.

### Means to Solve the Problem

In order to solve the above problem and achieve the object, a power semiconductor device according to the present disclosure includes: heat sink integrated power modules each including a power module and a heat sink that are integrated with each other, the heat sink including a plurality of heat dissipation fins provided on a heat sink base thereof and dissipating heat generated in the power module; a holding portion having a box shape including an inlet of air and an outlet of air that are provided facing each other, the holding portion including one surface interconnecting the inlet and the outlet, the one surface having a plurality of openings formed thereon; and a structural support provided inside the holding portion and supporting the one surface by bearing a load directed in a direction from the one surface toward the inside of the holding portion. The plurality of the heat dissipation fins of each of the heat sink integrated power modules is inserted in the holding portion from a corresponding one of the openings, and the heat sink base includes an outer peripheral edge supported on an adjacent region of the one surface in an in-plane direction of the heat sink base, the adjacent region being adjacent to the corresponding opening. The structural support is disposed at a position corresponding to space between the heat sink bases of the heat sink integrated power modules adjacent to each other in a width direction of the holding portion, the width direction being a direction orthogonal to a direction from the inlet toward the outlet.

### Effects of the Invention

The power semiconductor device according to the present disclosure has an effect of preventing bending of the holding portion to which the plurality of power modules and heat sinks are attached.

### BRIEF DESCRIPTION OF DRAWINGS

FIG. 1 is a plan view illustrating a configuration of a power semiconductor device according to a first embodiment.

FIG. 2 is a first cross-sectional view illustrating the configuration of the power semiconductor device according to the first embodiment, the cross-sectional view being taken along line II-II in FIG. 1.

FIG. 3 is a second cross-sectional view illustrating the configuration of the power semiconductor device according to the first embodiment, the cross-sectional view being taken along line III-III in FIG. 1.

FIG. 4 is a cross-sectional view of a heat sink integrated power module according to the first embodiment.

FIG. 5 is a cross-sectional view of a first modified heat sink integrated power module to which a first modified heat sink according to the first embodiment is attached.

FIG. 6 is a cross-sectional view of a second modified heat sink integrated power module to which a second modified heat sink according to the first embodiment is attached.

FIG. 7 is a cross-sectional view of a third modified heat sink integrated power module according to the first embodiment.

FIG. 8 is a top view illustrating an outer frame of the power semiconductor device according to the first embodiment.

FIG. 9 is a cross-sectional view illustrating the outer frame of the power semiconductor device according to the first embodiment, the cross-sectional view being taken along line IX-IX in FIG. 8.

FIG. 10 is a top view illustrating a housing of the power semiconductor device according to the first embodiment.

FIG. 11 is a first top view schematically illustrating an example of a procedure of a method of manufacturing the power semiconductor device according to the first embodiment.

FIG. 12 is a first cross-sectional view schematically illustrating an example of the procedure of the method of manufacturing the power semiconductor device according to the first embodiment.

FIG. 13 is a second top view schematically illustrating an example of the procedure of the method of manufacturing the power semiconductor device according to the first embodiment.

FIG. 14 is a second cross-sectional view schematically illustrating an example of the procedure of the method of manufacturing the power semiconductor device according to the first embodiment.

FIG. 15 is a third cross-sectional view schematically illustrating an example of the procedure of the method of manufacturing the power semiconductor device according to the first embodiment.

FIG. 16 is a third top view schematically illustrating an example of the procedure of the method of manufacturing the power semiconductor device according to the first embodiment.

FIG. 17 is a fourth top view schematically illustrating an example of the procedure of the method of manufacturing the power semiconductor device according to the first embodiment.

FIG. 18 is a fifth top view schematically illustrating an example of the procedure of the method of manufacturing the power semiconductor device according to the first embodiment.

FIG. 19 is a flowchart illustrating the procedure of the method of manufacturing the power semiconductor device according to the first embodiment.

FIG. 20 is a first schematic diagram for explaining an example of a size relationship between an opening of the housing and a heat sink base of the heat sink integrated power module in the power semiconductor device according to the first embodiment.

FIG. 21 is a second schematic diagram for explaining an example of the size relationship between the opening of the housing and the heat sink base of the heat sink integrated power module in the power semiconductor device according to the first embodiment.

FIG. 22 is a third schematic diagram for explaining an example of the size relationship between the opening of the housing and the heat sink base of the heat sink integrated power module in the power semiconductor device according to the first embodiment.

FIG. 23 is a first cross-sectional view illustrating a method of manufacturing a power semiconductor device of a comparative example according to the first embodiment.

FIG. 24 is a second cross-sectional view illustrating the method of manufacturing the power semiconductor device of the comparative example according to the first embodiment.

FIG. 25 is a schematic diagram for explaining an airflow inside a holding portion of the power semiconductor device according to the first embodiment.

FIG. 26 is a schematic diagram for explaining an airflow inside the holding portion of a power semiconductor device of a comparative example according to the first embodiment.

FIG. 27 is a first cross-sectional view illustrating an example of a method of fixing a structural support to the outer frame of the power semiconductor device according to the first embodiment.

FIG. 28 is a second cross-sectional view illustrating the example of the method of fixing the structural support to the outer frame of the power semiconductor device according to the first embodiment.

FIG. 29 is a third cross-sectional view illustrating the example of the method of fixing the structural support to the outer frame of the power semiconductor device according to the first embodiment.

FIG. 30 is a fourth cross-sectional view illustrating the example of the method of fixing the structural support to the outer frame of the power semiconductor device according to the first embodiment.

FIG. 31 is a first cross-sectional view illustrating an example of a method of fixing the structural support to the housing of the power semiconductor device according to the first embodiment.

FIG. 32 is a second cross-sectional view illustrating the example of the method of fixing the structural support to the housing of the power semiconductor device according to the first embodiment.

FIG. 33 is a flowchart illustrating a procedure of another method of manufacturing the power semiconductor device according to the first embodiment.

FIG. 34 is a first cross-sectional view illustrating a structure of the power semiconductor device in a case where an elastic structural support is applied to the power semiconductor device according to the first embodiment.

FIG. 35 is a second cross-sectional view illustrating the structure of the power semiconductor device in the case where the elastic structural support is applied to the power semiconductor device according to the first embodiment.

FIG. 36 is a first cross-sectional view for explaining a positional relationship among the structural support, the heat sink bases of the heat sink integrated power modules, and the housing in the power semiconductor device according to the first embodiment.

FIG. 37 is a second cross-sectional view for explaining a relationship among the structural support, the heat sink bases of the heat sink integrated power modules, and the housing in the power semiconductor device according to the first embodiment.

FIG. 38 is a third cross-sectional view for explaining the relationship among the structural support, the heat sink bases of the heat sink integrated power modules, and the housing in the power semiconductor device according to the first embodiment.

FIG. 39 is a first top view for explaining the shape and arrangement of the structural support in the power semiconductor device according to the first embodiment.

FIG. 40 is a second top view for explaining the shape and arrangement of the structural support in the power semiconductor device according to the first embodiment.

FIG. 41 is a third top view for explaining the shape and arrangement of the structural support in the power semiconductor device according to the first embodiment.

FIG. 42 is a fourth top view for explaining the shape and arrangement of the structural support in the power semiconductor device according to the first embodiment.

FIG. 43 is a cross-sectional view illustrating a configuration of a power semiconductor device according to a second embodiment.

FIG. 44 is a cross-sectional view illustrating the configuration of the power semiconductor device according to the second embodiment.

FIG. 45 is a cross-sectional view illustrating a configuration of heat sink integrated power modules according to a third embodiment.

FIG. 46 is a cross-sectional view illustrating a configuration of a power semiconductor device according to the third embodiment.

### DESCRIPTION OF EMBODIMENTS

Hereinafter, a power semiconductor device and a method of manufacturing the power semiconductor device according to embodiments will be described in detail with reference to the drawings.

### First Embodiment

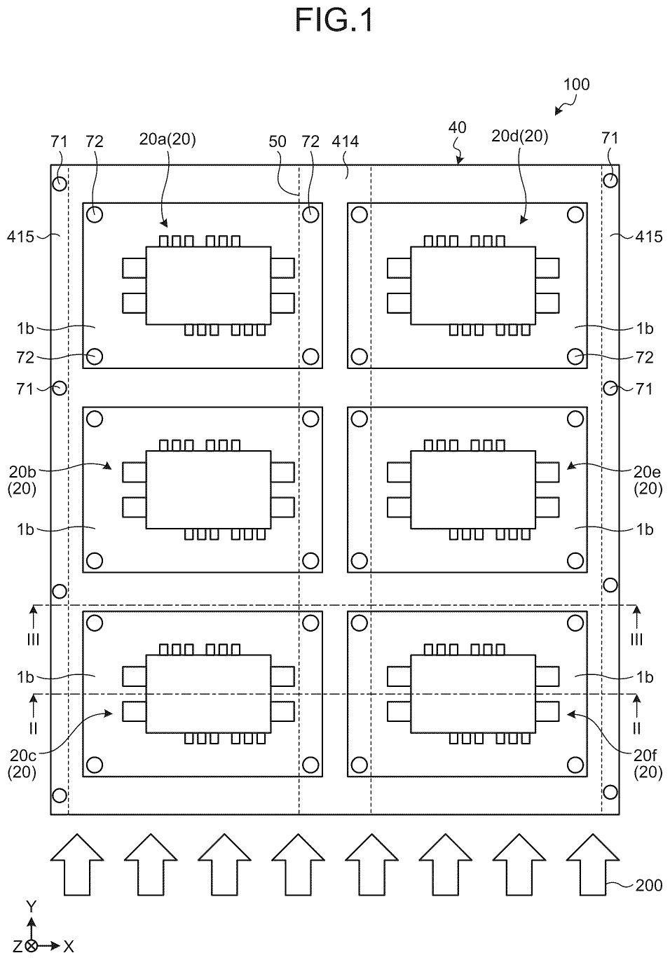

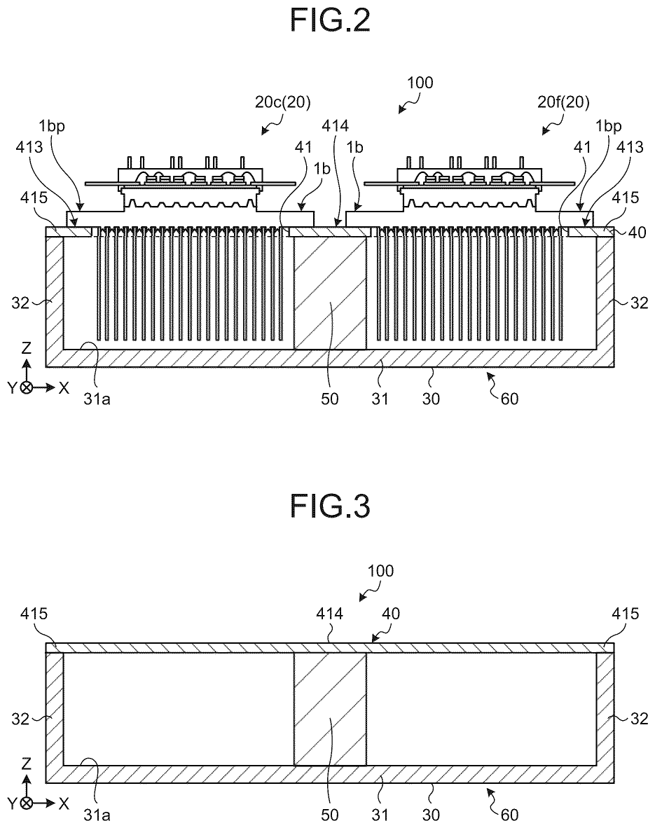

FIG. 1 is a plan view illustrating a configuration of a power semiconductor device 100 according to a first embodiment. FIG. 2 is a first cross-sectional view illustrating the configuration of the power semiconductor device 100 according to the first embodiment, the cross-sectional view being taken along line II-II in FIG. 1. FIG. 3 is a second cross-sectional view illustrating the configuration of the power semiconductor device 100 according to the first embodiment, the cross-sectional view being taken along line III-III in FIG. 1. Note that, in the cross-sectional views, hatching is partially omitted for ease of viewing.

In the first embodiment, a left-right direction in FIG. 1 to FIG. 3 coincides with a left-right direction of the power semiconductor device 100 and components of the power semiconductor device 100. The left-right direction corresponds to an X direction in FIG. 1 to FIG. 3, and corresponds to a width direction of the power semiconductor device 100 and the components of the power semiconductor device 100. In addition, a depth direction that pierces through the front face of FIG. 2 and FIG. 3 and an up-down direction in FIG. 1 coincide with a depth direction of the power semiconductor device 100 and the components of the power semiconductor device 100. The depth direction corresponds to a Y direction in FIG. 1 to FIG. 3, and corresponds to the depth direction of the power semiconductor device 100 and the components of the power semiconductor device 100. Moreover, the depth direction can be rephrased as a direction of travel of an air flow 200 blown from a blowing system (not illustrated) to the power semiconductor device 100, that is, a blowing direction or an air inflow direction in the power semiconductor device 100. The depth direction can also be rephrased as a direction of travel of the air flow 200 inside a holding portion 60. In addition, an up-down direction in FIG. 2 and FIG. 3 and a depth direction that pierces through the front face of FIG. 1 coincide with an up-down direction of the power semiconductor device 100 and the components of the power semiconductor device 100. The up-down direction corresponds to a Z direction in FIG. 1 to FIG. 3, and corresponds to a height direction of the power semiconductor device 100 and the components of the power semiconductor device 100.

In addition, a near side in the depth direction that pierces through the front face of FIG. 2 and FIG. 3 and a lower side of FIG. 1 coincide with a front side of the power semiconductor device 100 and a heat sink integrated power module 20. A far side in the depth direction that pierces through the front face of FIG. 2 and FIG. 3 and an upper side of FIG. 1 coincide with a back side of the power semiconductor device 100 and the heat sink integrated power module 20. Note that “left-right”, “up-down”, “front”, and “back” are the expressions used for the sake of convenience and do not mean actual “left-right”, “up-down”, “front”, and “back” directions, and these directions may be reversed.

In the power semiconductor device 100, a plurality of the heat sink integrated power modules 20 is mounted to the holding portion 60. The power semiconductor device 100 includes the plurality of the heat sink integrated power modules 20, a structural support 50, and the holding portion 60. In FIG. 1, as an example of a power semiconductor device equipped with a plurality of the heat sink integrated power modules 20 according to the first embodiment, the power semiconductor device 100 equipped with six pieces of the heat sink integrated power modules 20 arranged in two columns and three rows is illustrated.

The holding portion 60 houses and holds a part of the plurality of the heat sink integrated power modules 20 in the power semiconductor device 100. That is, the plurality of the heat sink integrated power modules 20 is held by the holding portion 60 while being partially housed in the holding portion 60. The holding portion 60 includes a housing 40 and an outer frame 30.

In the power semiconductor device 100 illustrated in FIG. 1, the heat sink integrated power modules 20 including a heat sink integrated power module 20a, a heat sink integrated power module 20b, a heat sink integrated power module 20c, a heat sink integrated power module 20d, a heat sink integrated power module 20e, and a heat sink integrated power module 20f are attached to the holding portion 60. Note that the number of the heat sink integrated power modules 20 attached in the power semiconductor device 100 is not limited to six. For example, two or more of the heat sink integrated power modules 20 may be attached to the holding portion 60 in the left-right direction. In such a mode as well, an effect of the power semiconductor device 100 described later can be obtained.

Inside the holding portion 60, the air flow 200 blown from the blowing system flows from the front side toward the back side. Note that the air flow 200 may flow in a direction from the back side toward the front side.

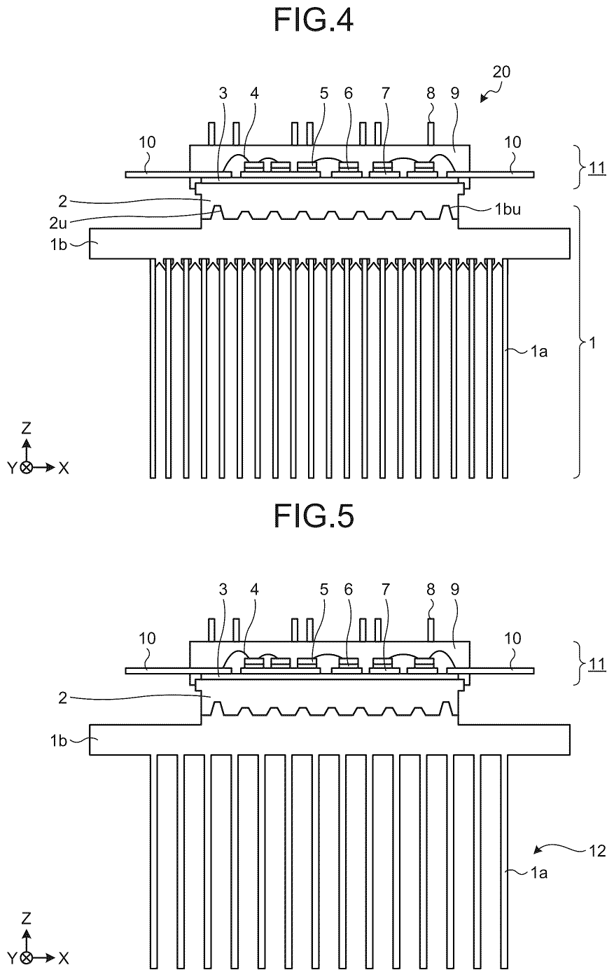

The heat sink integrated power module 20 is a power semiconductor module mounted in the power semiconductor device 100, and is a resin-molded power module. FIG. 4 is a cross-sectional view of the heat sink integrated power module 20 according to the first embodiment. The heat sink integrated power module 20 according to the first embodiment includes a heat sink 1, a fin base 2, an insulating sheet 3, wiring wires 4, semiconductor elements 5, solders 6, metal conductors 7, control terminals 8, a sealing resin 9, and main terminals 10.

The heat sink 1 also includes a plurality of heat dissipation fins 1a and a heat sink base 1b. Moreover, the insulating sheet 3, the wiring wires 4, the semiconductor elements 5, the solders 6, the metal conductors 7, the control terminals 8, the sealing resin 9, and the main terminals 10 constitute a power module 11 according to the first embodiment. Therefore, the heat sink integrated power module 20 according to the first embodiment is configured by joining the heat sink 1 and the power module 11 via the fin base 2. That is, in the heat sink integrated power module 20, the power module 11 and the heat sink 1 are integrated, the heat sink 1 dissipating heat generated in the power module 11 with the plurality of the heat dissipation fins 1a provided on the heat sink base 1b.

In the heat sink integrated power module 20, the heat sink 1 is connected to a lower surface side of the power module 11, and dissipation of heat generated in the semiconductor elements 5 of the power module 11 is improved. That is, in the heat sink integrated power module 20, the heat generated in the semiconductor elements 5 of the power module 11 is dissipated from the heat sink 1, so that the dissipation of the heat generated in the power module 11 is improved. The heat sink integrated power module 20 is a greaseless power module that does not use thermally conductive grease between the power module 11 and the heat sink 1. Thus, compared to a case where the thermally conductive grease is used between the power module 11 and the heat sink 1, the heat sink integrated power module 20 has higher heat dissipation property for the heat generated in the power module 11 and has higher heat dissipation performance.

The heat sink 1 is a swaged heat sink in which the heat dissipation fins 1a and the heat sink base 1b are integrated by “swaging”.

The heat dissipation fin 1a is a thin plate heat dissipating component having a rectangular shape. The heat dissipation fin 1a is made of a metal material having relatively high thermal conductivity such that the heat generated in the semiconductor elements 5 of the power module 11 can be dissipated. In one example, the heat dissipation fin 1a is made of a metal material that is not easily corroded, such as aluminum and an aluminum alloy. When a rolled material of the above-described metal material such as aluminum is used for the heat dissipation fin 1a, both the workability of the heat dissipation fin 1a and the heat dissipation performance for the heat generated in the semiconductor elements 5 can be achieved.

Each of the plurality of the heat dissipation fins 1a is inserted into a fin insertion groove (not illustrated) formed on one surface side of the heat sink base 1b and swaged, thereby being fixed to the heat sink base 1b. The heat dissipation fins 1a are disposed so as to sandwich the heat sink base 1b with the fin base 2.

The heat sink base 1b is a flat plate component having a rectangular shape in an in-plane direction of the heat sink base 1b, and is a component to which the plurality of the heat dissipation fins 1a is fixed, serving as a base of the heat sink 1. The heat sink base 1b is made of a metal material having relatively high thermal conductivity such that the heat generated in the semiconductor elements 5 of the power module 11 can be efficiently transferred to the heat dissipation fins 1a. In one example, the heat sink base 1b is made of a metal material that is not easily corroded, such as aluminum and an aluminum alloy. The heat sink base 1b is manufactured by a processing method such as cutting, die casting, forging, or extrusion.

The fin base 2 is a flat plate component having a rectangular shape smaller than that of the heat sink base 1b, and is a connection component that connects the power module 11 and the heat sink 1. The fin base 2 is made of a metal material having relatively high thermal conductivity such that the heat generated in the semiconductor elements 5 of the power module 11 can be efficiently transferred from the power module 11 to the heat sink 1. In one example, the fin base 2 is made of a metal material that is not easily corroded, such as aluminum and an aluminum alloy. The fin base 2 is manufactured by a processing method such as cutting, die casting, forging, or extrusion.

Note that the material of each of the heat dissipation fins 1a, the heat sink base 1b, and the fin base 2 is not limited to the above-described aluminum-based material, and may be other materials. That is, a combination of the materials of the heat dissipation fins 1a, the heat sink base 1b, and the fin base 2 may be a combination of materials different from those described above. For example, in terms of heat dissipation capability, when the heat dissipation fins 1a are each a copper-based plate component having a thermal conductivity higher than that of the aluminum-based material, the heat dissipation capability of the heat dissipation fins 1a is further improved as compared with the case where the heat dissipation fins 1a are each the plate component made of the aluminum-based material.

In the case where the swaged heat sink in which the heat dissipation fins 1a and the heat sink base 1b are integrated by swaging is adopted for the heat sink 1, there is no processing restriction on the aspect ratio unlike when the heat sink is manufactured by die casting and extrusion, so that the heat dissipation fins 1a can be freely designed, and the heat dissipation capability of the heat sink 1 can be improved. Note that the heat sink 1 is not limited to the swaged heat sink, and may be a heat sink manufactured by another processing method.

FIG. 5 is a cross-sectional view of a first modified heat sink integrated power module to which a first modified heat sink 12 according to the first embodiment is attached. In FIG. 5, the same components as those in FIG. 4 are denoted by the same reference numerals as those of such components in FIG. 4. In the first modified heat sink 12, the heat dissipation fins 1a and the heat sink base 1b are integrally manufactured by extrusion.

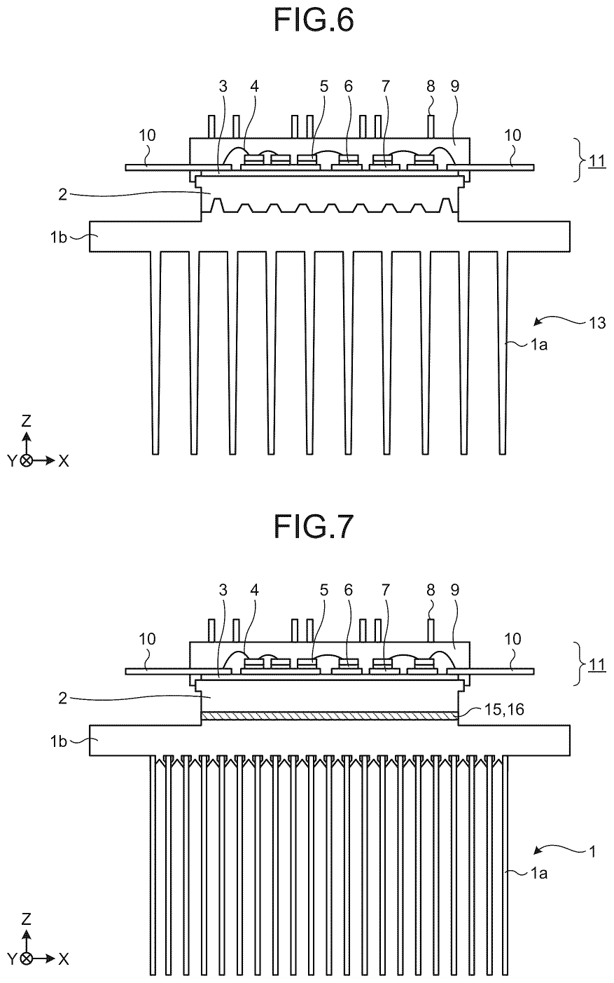

FIG. 6 is a cross-sectional view of a second modified heat sink integrated power module to which a second modified heat sink 13 according to the first embodiment is attached. In FIG. 6, the same components as those in FIG. 4 are denoted by the same reference numerals as those of such components in FIG. 4. In the second modified heat sink 13, the heat dissipation fins 1a and the heat sink base 1b are integrally manufactured by die casting.

Also, in the heat sink integrated power module 20, a heat sink manufactured by cutting or forging may be used.

FIG. 7 is a cross-sectional view of a third modified heat sink integrated power module according to the first embodiment. In the third modified heat sink integrated power module, the power module 11 and the heat sink 1 are connected by a bonding material 15 such as solder or an adhesive 16.

The structures illustrated in FIG. 5 to FIG. 7 can also obtain the effect of the greaseless power module that high heat dissipation performance can be achieved as described above.

The insulating sheet 3 insulates components sealed by the sealing resin 9 from the heat sink base 1b, and also dissipates the heat generated by the semiconductor elements 5 to the heat sink base 1b. The insulating sheet 3 has heat dissipation performance higher than or equal to that of the sealing resin 9.

The wiring wires 4 electrically connect the semiconductor elements 5 to each other, and electrically connect the semiconductor elements 5 to the main terminals 10.

The semiconductor elements 5 are semiconductor elements for power control. Examples of the semiconductor elements 5 include rectifier diodes, power transistors, thyristors, and insulated gate bipolar transistors (IGBTs). The semiconductor elements 5 are each exemplified by an element formed of silicon (Si) or an element formed of a wide band gap semiconductor having a band gap wider than that of silicon. Examples of the wide band gap semiconductor include silicon carbide (SiC), a gallium nitride-based material, and diamond. Since the semiconductor element 5 using the wide band gap semiconductor has a high allowable current density and a low power loss, the heat sink integrated power module 20 and the power semiconductor device 100 can be downsized.

The solders 6 are bonding materials for bonding the semiconductor elements 5 and the metal conductors 7. Note that the bonding materials for bonding the semiconductor elements 5 and the metal conductors 7 are not limited to the solders 6.

The metal conductors 7 are substrates on which the semiconductor elements 5 are mounted, and dissipate the heat generated by the semiconductor elements 5 to the insulating sheet 3.

The control terminals 8 and the main terminals 10 are connected to the semiconductor elements 5, and supply power to the semiconductor elements 5 or transmit signals between the semiconductor elements 5 and an external device.

The sealing resin 9 constitutes a casing of the power module 11. The sealing resin 9 is formed of a thermosetting resin such as epoxy, and secures insulation between the members disposed inside. The sealing resin 9 is, for example, a transfer mold formed by transfer molding. However, the method of molding the sealing resin 9 is not limited to transfer molding.

Next, a method of manufacturing the heat sink integrated power module 20 configured as described above will be described.

First, the semiconductor element 5 is die-bonded to the metal conductor 7 using the solder 6. Next, the semiconductor element 5 and another piece of the semiconductor elements 5 are wire-bonded by the wiring wire 4, and are electrically connected. In addition, some of the semiconductor elements 5 and the control terminal 8 or the main terminal 10 are wire-bonded by the wiring wire 4, and are electrically connected. Next, the insulating sheet 3 is temporarily attached on one surface of the fin base 2.

After that, the fin base 2 with the insulating sheet 3 temporarily attached on one surface thereof, the metal conductors 7 having completed the die bonding of the semiconductor elements 5 and the wire bonding by the wiring wires 4 as described above, and the control terminals 8 and the main terminals 10 are integrated using the sealing resin 9, whereby an assembly is prepared in which the heat sink integrated power module 20 and the fin base 2 are assembled.

Furthermore, fin base unevennesses 2u provided on another surface side of the fin base 2 and heat sink base unevennesses 1bu provided on one surface of the heat sink base 1b are fitted and fixed by press working, whereby the assembly and the heat sink base 1b are integrated. As a result, the heat sink integrated power module 20 illustrated in FIG. 1 is formed.

In the method of manufacturing the heat sink integrated power module 20 described above, the fin base 2 and the heat sink base 1b are integrated by press working, and thus there is a concern about occurrence of problems such as damage to the semiconductor elements 5 at the time of press working, cracking of the semiconductor elements 5, a change in characteristics of the semiconductor elements 5, cracking of the sealing resin 9, a decrease in pressure resistance of the insulating sheet 3, and the members of the heat sink integrated power module 20 falling off of each other. Therefore, it is preferable that a press load when the assembly and the heat sink base 1b are integrated is as low as possible.

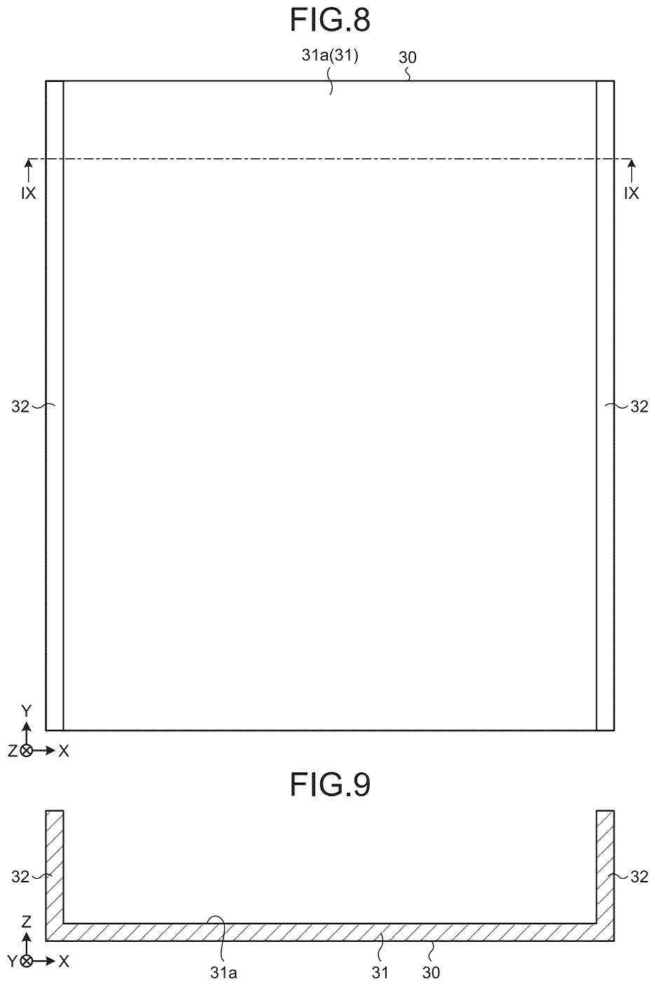

FIG. 8 is a top view illustrating the outer frame 30 of the power semiconductor device 100 according to the first embodiment. FIG. 9 is a cross-sectional view illustrating the outer frame 30 of the power semiconductor device 100 according to the first embodiment, the cross-sectional view being taken along line IX-IX in FIG. 8.

The outer frame 30 supports the housing 40 to which the heat sink integrated power module 20 is attached, and forms a path for the air flow 200 blown from the blowing system. The outer frame 30, which has a rectangular parallelepiped box shape opened at upper, front, and back sides thereof, includes a bottom surface portion 31 and two side surface portions 32 rising vertically upward from both right and left ends of the bottom surface portion 31. That is, as illustrated in FIGS. 2, 3, 8, and 9, the outer frame 30 has a U-shaped cross section in the left-right direction, and the structure of the outer frame 30 is closed at other sides than the upper side having the housing 40 attached thereto, the front side, and the back side. Note that the outer frame 30 does not necessarily have to have the shape in which the surfaces other than the surfaces on the upper side, the front side, and the back side are closed, and an opening may be formed as necessary.

In addition, the “U shape” includes not only a shape having no corner but also the shape having corners as illustrated in FIGS. 2, 3, 8, and 9. That is, the “U shape” includes a shape in which a bend is continuously formed by a curve and a shape in which a bend is formed by a bent portion.

In the outer frame 30, an internal space surrounded by the bottom surface portion 31 and the two side surface portions 32 form the path for the air blown from the blowing system. In the outer frame 30, the front side that is open is an inlet for the air blown from the blowing system. In the outer frame 30, the back side that is open is an outlet for the air flowing into the outer frame 30 from the inlet and flowing through the outer frame 30. The inlet for the air in the outer frame 30 can be rephrased as an inlet for the air in the holding portion 60. The outlet for the air in the outer frame 30 can be rephrased as an outlet for the air in the holding portion 60.

In order to support the weight of the housing 40, the heat sink integrated power modules 20, and the parts connected to the heat sink integrated power modules 20, the outer frame 30 is made of a material having rigidity capable of supporting the above components. In addition, in terms of the product weight of the power semiconductor device 100, the outer frame 30 is preferably reduced in thickness and weight as much as possible while having the rigidity capable of supporting the above components. For example, a plated steel plate can achieve the rigidity capable of supporting the above components, the reduction in thickness, and the reduction in weight, and is a preferable material to be used for the outer frame 30. Note that a material other than the plated steel plate can be used for the outer frame 30.

The housing 40 is an attachment plate for the heat sink integrated power module 20 to which the heat sink integrated power module 20 is attached and mounted. As illustrated in FIGS. 2 and 3, the housing 40 is placed on the two side surface portions 32 of the outer frame 30. An in-plane direction of the housing 40, an in-plane direction of the bottom surface portion 31 of the outer frame 30, and an in-plane direction of the heat sink base 1b of the heat sink integrated power module 20 are parallel to one another.

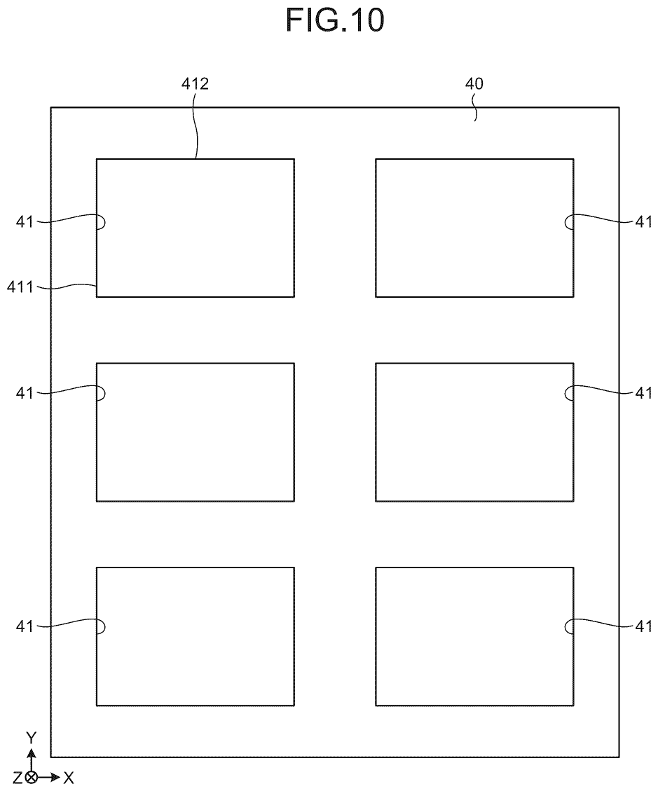

FIG. 10 is a top view illustrating the housing 40 of the power semiconductor device 100 according to the first embodiment. As illustrated in FIG. 10, the housing 40 has a plate shape, and includes a plurality of openings 41 into which portions of the heat sink integrated power modules 20 are inserted. In the housing 40, the plurality of the openings 41 formed corresponds to the number of the heat sink integrated power modules 20 mounted and the size of the heat dissipation fins 1a. In the housing 40 illustrated in FIG. 10, six of the openings 41 are formed for mounting six of the heat sink integrated power modules 20.

The opening 41 has a rectangular shape in the in-plane direction of the housing 40. Note that the shape of the opening 41 is not limited to the rectangular shape, and need only be formed in accordance with the shape of the heat sink integrated power module 20. The opening 41 has a size that allows for insertion of the entire heat dissipation fins 1a of the heat sink integrated power module 20 and does not allow for insertion of an outer peripheral edge 1bp of the heat sink base 1b in the in-plane direction of the housing 40. That is, the opening 41 has a size and a shape that allow for insertion of the entire heat dissipation fins 1a of the heat sink integrated power module 20 but do not allow for insertion of the heat sink base 1b in the in-plane direction of the housing 40. A relationship among the sizes of the opening 41, the heat sink integrated power module 20, the heat sink base 1b, and the heat dissipation fins 1a will be described later.

In order to support the weight of the heat sink integrated power modules 20 and the parts connected to the heat sink integrated power modules 20, the housing 40 is made of a material having rigidity capable of supporting the above components. In addition, in terms of the product weight of the power semiconductor device 100, the housing 40 is preferably reduced in thickness and weight as much as possible while having the rigidity capable of supporting the above components. For example, a plated steel plate can achieve the rigidity capable of supporting the above components, the reduction in thickness, and the reduction in weight, and is a preferable material to be used for the housing 40. Note that a material other than the plated steel plate can be used for the housing 40.

As illustrated in FIG. 2, the heat dissipation fins 1a of the heat sink 1 of the heat sink integrated power module 20 are inserted in the corresponding one of the plurality of the openings 41 from the outside of the holding portion 60. With the heat dissipation fins 1a housed inside the holding portion 60, the outer peripheral edge 1bp of the heat sink base 1b of the housing 40 is placed on an adjacent region 413 adjacent to the opening 41. The housing 40, which constitutes one surface of the holding portion 60, is supported by ends of the two side surface portions 32 that are free ends of the U shape of the outer frame 30.

As a result, the housing 40 holds the heat sink base 1b in the adjacent region 413, thereby holding the heat sink integrated power module 20. That is, in each of the plurality of the heat sink integrated power modules 20, the plurality of the heat dissipation fins 1a is inserted into the holding portion 60 from the opening 41, and in the in-plane direction of the heat sink base 1b, the outer peripheral edge 1bp of the heat sink base 1b is supported on the adjacent region 413 adjacent to the opening 41 in the housing 40 constituting one surface of the holding portion 60.

Therefore, the holding portion 60, which is constituted by the outer frame 30 and the thus configured housing 40, has a box shape having the inlet of air and the outlet of air provided facing each other, and the one surface interconnecting the inlet and the outlet, the one surface being constituted by the housing 40 and having the plurality of the openings 41 formed therein.

The structural support 50, which is provided inside the holding portion 60, bears a load directed in a direction from the housing 40 constituting one surface of the holding portion 60 toward the inside of the holding portion 60, such that the structural support 50 supports the housing 40 and the heat sink integrated power modules 20 mounted to the housing 40. The structural support 50 is disposed at a position corresponding to the space between the heat sink bases 1b of the heat sink integrated power modules 20 adjacent to each other in a width direction of the holding portion 60. The width direction of the holding portion 60 is a direction orthogonal to a direction from the inlet of the holding portion 60 toward the outlet of the holding portion 60, and coincides with the left-right direction. The direction from the inlet of the holding portion 60 toward the outlet of the holding portion 60 corresponds to the Y direction. The structural support 50 extends continuously in the direction from the inlet toward the outlet in a region from the inlet of the holding portion 60 to the outlet of the holding portion 60. The structural support 50 is fixed to the outer frame 30, and an upper surface of the structural support 50 is in contact with the housing 40. The structural support 50 has a rod shape with a rectangular cross section perpendicular to a longitudinal direction. Note that the shape of the structural support 50 is not limited as long as the function of the structural support 50 can be fulfilled.

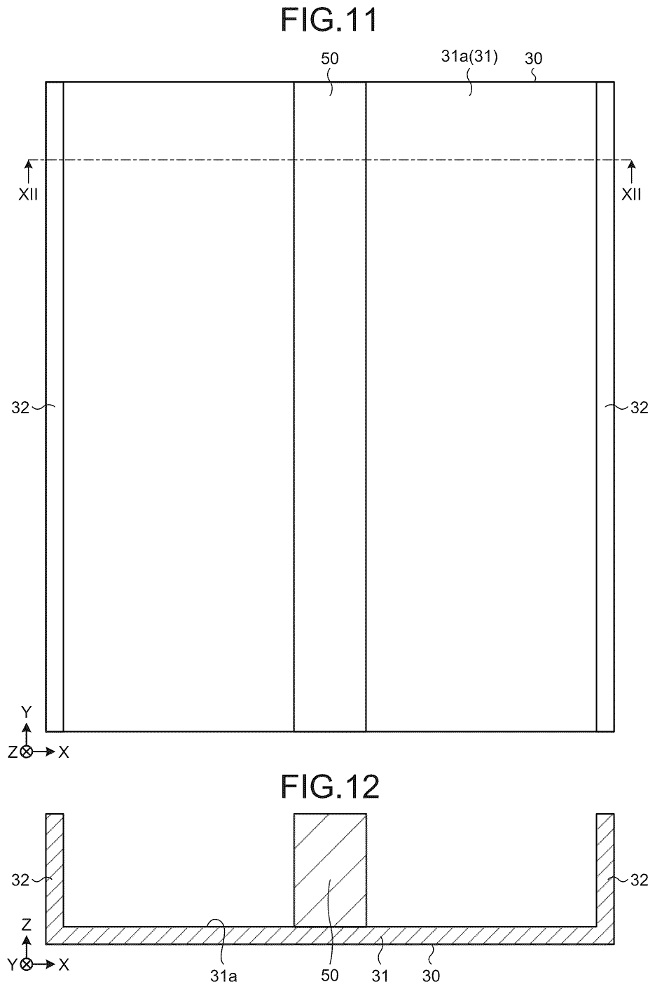

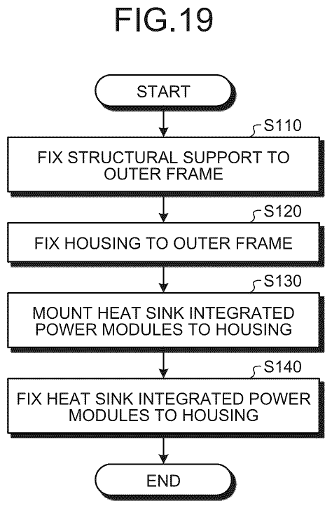

Next, a method of manufacturing the power semiconductor device 100 configured as described above will be described. FIGS. 11 to 18 are views each schematically illustrating an example of a procedure of the method of manufacturing the power semiconductor device 100 according to the first embodiment. FIG. 19 is a flowchart illustrating the procedure of the method of manufacturing the power semiconductor device 100 according to the first embodiment.

First, in step S110, the structural support 50 is attached and fixed to the outer frame 30. FIG. 11 is a first top view schematically illustrating an example of the procedure of the method of manufacturing the power semiconductor device 100 according to the first embodiment. FIG. 12 is a first cross-sectional view schematically illustrating an example of the procedure of the method of manufacturing the power semiconductor device 100 according to the first embodiment. FIG. 12 is the cross-sectional view taken along line XII-XII in FIG. 11.

Specifically, as illustrated in FIGS. 11 and 12, the structural support 50 is attached and fixed to an inner surface 31a of the bottom surface portion 31 of the outer frame 30. In a state where a cross section of the structural support 50 perpendicular to a longitudinal direction thereof is perpendicular to the inner surface 31a of the bottom surface portion 31 of the outer frame 30, and the longitudinal direction is parallel to the two side surface portions 32 of the outer frame 30, the structural support 50 is attached to a central portion in the left-right direction of the inner surface 31a of the bottom surface portion 31. A method of fixing the structural support 50 to the outer frame 30 includes screw fastening, for example. Note that the method of fixing the structural support 50 to the outer frame 30 is not limited to screw fastening. For example, the structural support 50 may be fixed to the inner surface 31a of the bottom surface portion 31 of the outer frame 30 by welding.

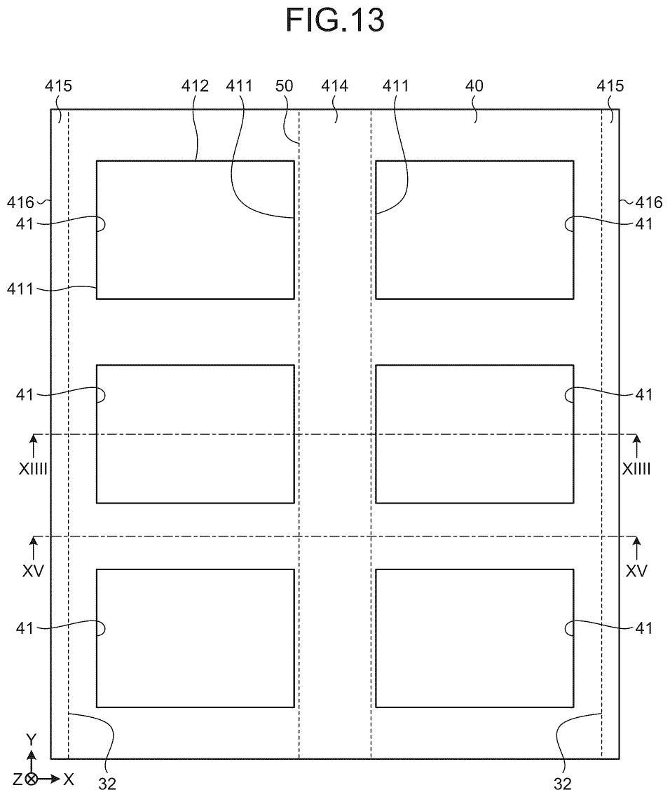

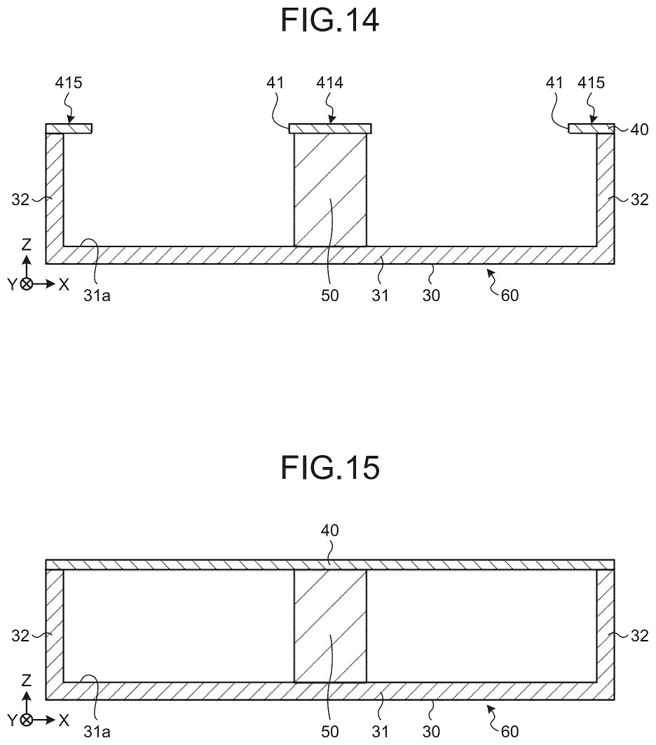

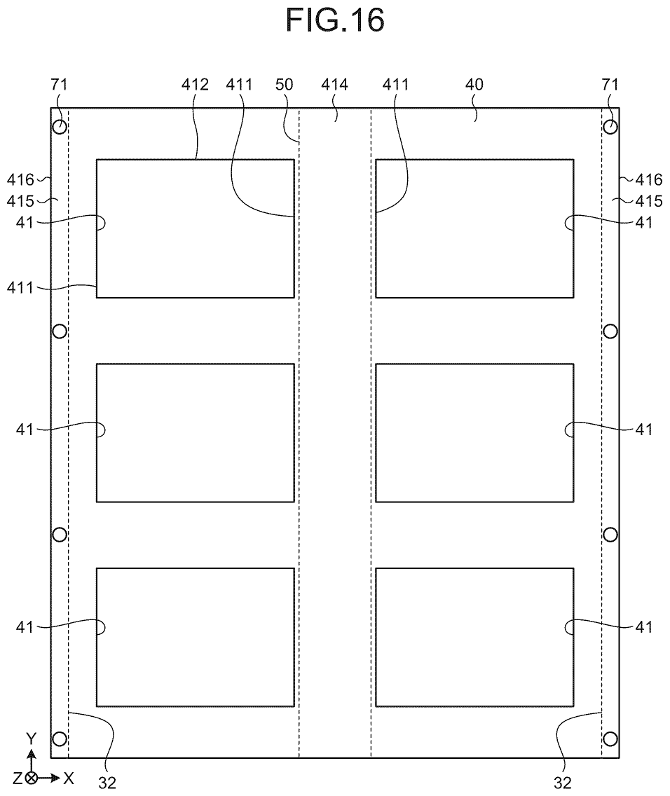

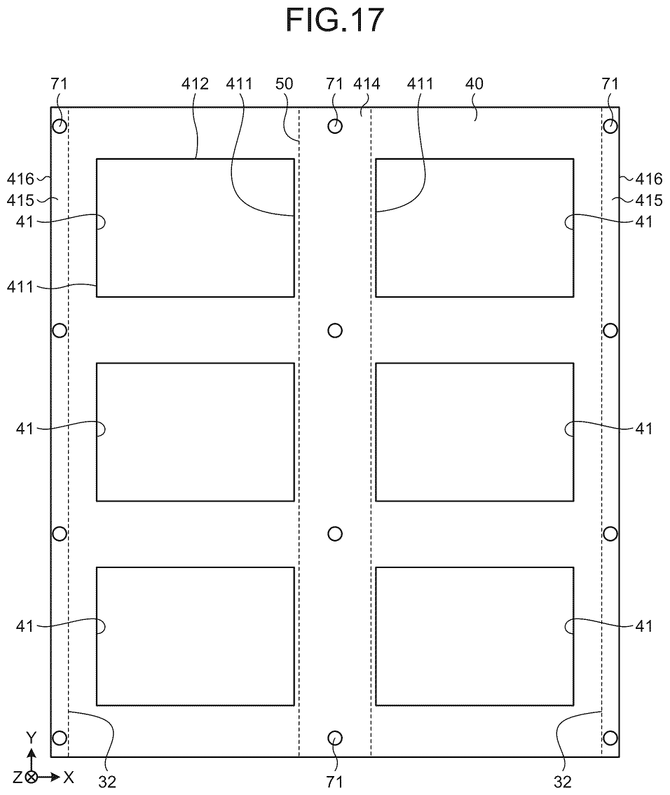

Next, in step S120, the housing 40 is screwed and fixed to the outer frame 30 using housing fixing screws 71. FIG. 13 is a second top view schematically illustrating an example of the procedure of the method of manufacturing the power semiconductor device 100 according to the first embodiment. FIG. 14 is a second cross-sectional view schematically illustrating an example of the procedure of the method of manufacturing the power semiconductor device 100 according to the first embodiment. FIG. 15 is a third cross-sectional view schematically illustrating an example of the procedure of the method of manufacturing the power semiconductor device 100 according to the first embodiment. FIG. 16 is a third top view schematically illustrating an example of the procedure of the method of manufacturing the power semiconductor device 100 according to the first embodiment. FIG. 17 is a fourth top view schematically illustrating an example of the procedure of the method of manufacturing the power semiconductor device 100 according to the first embodiment. FIG. 14 is the cross-sectional view taken along line XIIII-XIIII in FIG. 13. FIG. 15 is the cross-sectional view taken along line XV-XV in FIG. 13.

Specifically, as illustrated in FIGS. 13 to 15, the housing 40 is placed on the outer frame 30. At this time, end regions 415 in the left-right direction of the housing 40 are placed on the side surface portions 32 of the outer frame 30. Also, a center region 414 in the left-right direction of the housing 40 is placed on the structural support 50. In the housing 40, a region between an opening's short side 411 and a housing's long side 416 in the left-right direction is defined as the end region 415. Moreover, in the housing 40, a region corresponding to a position between the opening's short sides 411 adjacent to each other in the left-right direction is defined as the center region 414.

Then, as illustrated in FIG. 16, at both ends in the left-right direction, the housing fixing screws 71 are fastened from above the end regions 415 of the housing 40, whereby the housing 40 is screwed and fixed to the outer frame 30 at the end regions 415. Furthermore, as illustrated in FIG. 17, at a center portion in the left-right direction, the housing fixing screws 71 may be fastened from above the center region 414 of the housing 40, whereby the housing 40 may be screwed and fixed to the structural support 50 at the center region 414.

In the outer frame 30, screw holes (not illustrated) are formed in advance at the locations where the housing fixing screws 71 are screwed. The positions where the housing fixing screws 71 are screwed in the outer frame 30 are the positions on upper surfaces of the two side surface portions 32 of the outer frame 30. Moreover, in the housing 40, screw holes (not illustrated) or through holes (not illustrated) are formed in advance at the locations where the housing fixing screws 71 are screwed. The positions where the housing fixing screws 71 are screwed in the housing 40 are the positions corresponding to the screw holes in the outer frame 30 in the end regions 415. Moreover, in the structural support 50, screw holes (not illustrated) are formed in advance at the locations where the housing fixing screws 71 are screwed. The positions where the housing fixing screws 71 are screwed in the structural support 50 are the positions corresponding to the screw holes or the through holes in the center region 414 of the housing 40 on the upper surface of the structural support 50 fixed to the outer frame 30.

The housing 40 is screwed and fixed to the outer frame 30 at the end regions 415 and is screwed and fixed to the structural support 50 at the center region 414, so that the housing 40 is more firmly fixed to the other components in the holding portion 60, and vibration resistance of the holding portion 60 and the power semiconductor device 100 is further improved.

Next, in step S130, the heat sink integrated power modules 20 are mounted to the housing 40. Specifically, the heat dissipation fins 1a of the heat sink integrated power modules 20 are inserted from above the openings 41 of the housing 40, and thus the heat sink integrated power modules 20 are mounted to the housing 40.

Here, as illustrated in FIG. 2, the heat sink integrated power modules 20 are mounted while the heat dissipation fins 1a are housed inside the holding portion 60, and the outer peripheral edges 1bp of the heat sink bases 1b are placed on the adjacent regions 413 adjacent to the openings 41. As a result, the heat sink bases 1b are supported at the adjacent regions 413 of the housing 40, and the heat sink integrated power modules 20 are held by the housing 40. In addition, the heat sink integrated power modules 20 are mounted to the housing 40 such that, in the in-plane direction of the housing 40, the positions of the centers of the openings 41 of the housing 40 coincide with the positions of the centers of the heat sink bases 1b. Moreover, the heat sink integrated power modules 20 are mounted to the housing 40 with the depth direction of the plurality of the heat dissipation fins 1a in the heat sinks 1 being parallel to the opening's short sides 411, and with an arrangement direction of the heat dissipation fins 1a, which is the direction in which the plurality of the heat dissipation fins 1a is arranged in the heat sinks 1, being parallel to opening's long sides 412.

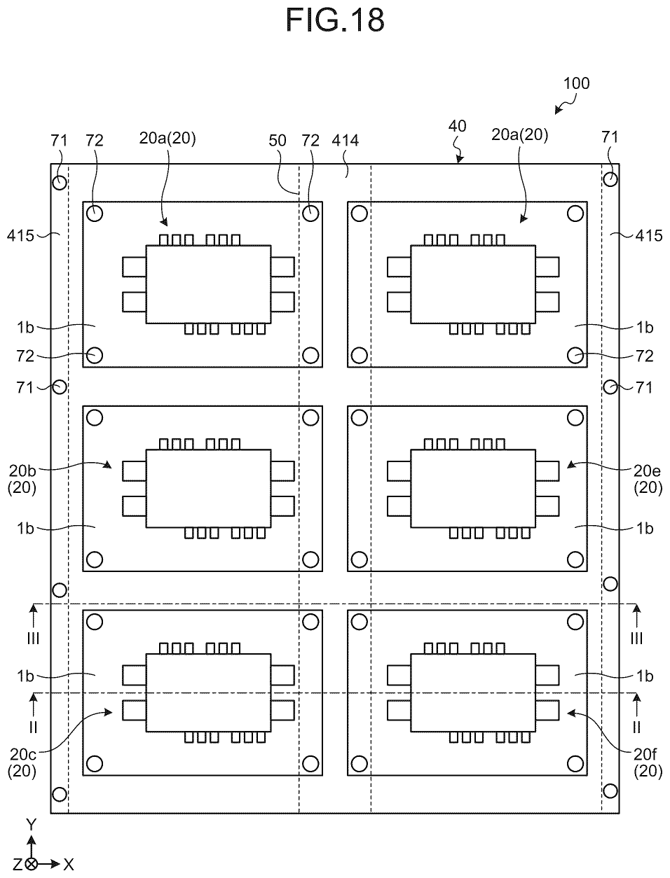

Next, in step S140, the heat sink integrated power modules 20 are screwed and fixed to the housing 40. FIG. 18 is a fifth top view schematically illustrating an example of the procedure of the method of manufacturing the power semiconductor device 100 according to the first embodiment.

Specifically, as illustrated in FIG. 18, in peripheral regions of four corners of each of the heat sink bases 1b in the in-plane direction of the heat sink bases 1b of the heat sink integrated power modules 20, power module fixing screws 72 are fastened from above the heat sink bases 1b, so that the heat sink bases 1b are screwed and fixed to the housing 40 at the peripheral regions of the corners. As a result, the heat sink integrated power modules 20 are screwed and fixed to the housing 40 at the peripheral regions of the corners of the heat sink bases 1b.

In the housing 40, screw holes (not illustrated) are formed in advance at the locations where the power module fixing screws 72 are screwed. In the housing 40, the positions where the power module fixing screws 72 are screwed are the positions on the side of the openings 41 in the end regions 415 and the positions on the side of the openings 41 in the center region 414. In the heat sink bases 1b, screw holes (not illustrated) or through holes (not illustrated) are formed in advance at the locations where the power module fixing screws 72 are screwed. The positions where the power module fixing screws 72 are screwed in the heat sink bases 1b are the positions corresponding to the screw holes in the end regions 415 of the housing 40. As a result, as illustrated in FIG. 18, the heat sink integrated power modules 20 according to the first embodiment are manufactured.

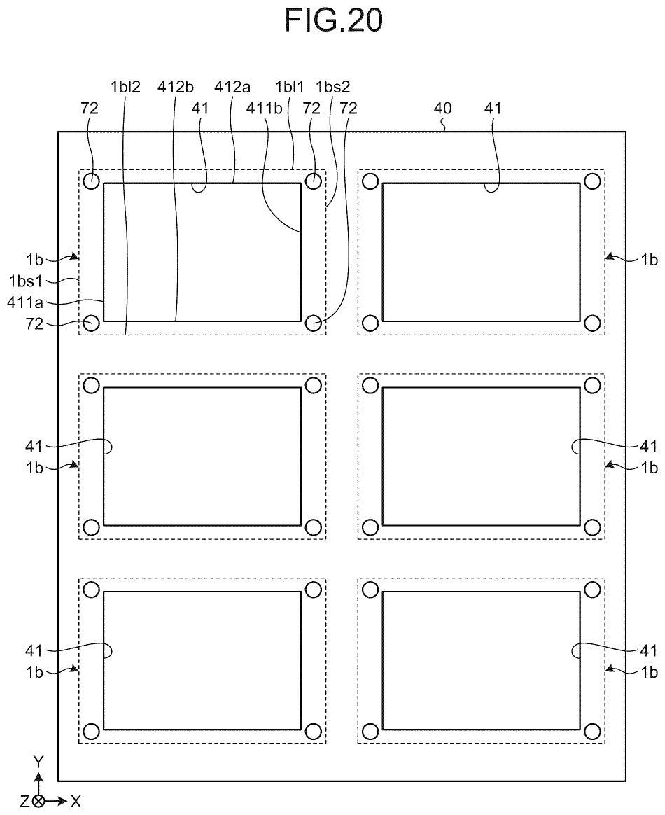

Next, a size relationship between the opening 41 formed in the housing 40 and the heat sink base 1b of the heat sink integrated power module 20 will be described. FIG. 20 is a first schematic diagram for explaining an example of the size relationship between the opening 41 of the housing 40 and the heat sink base 1b of the heat sink integrated power module 20 in the power semiconductor device 100 according to the first embodiment. In FIG. 20, in a top view of the housing 40, the positions of the heat sink bases 1b of the heat sink integrated power modules 20 mounted to the housing 40 are indicated by broken lines.

In the power semiconductor device 100, in order for the heat sink integrated power modules 20 and the housing 40 to be fixed by screwing the heat sink bases 1b and the housing 40, as illustrated in FIG. 20, conditions expressed by the following Formulas (1) to (4) are satisfied in the in-plane direction of the housing 40. The opening 41 in the following Formulas (1) to (4) is the opening 41 of the housing 40.

The length of an opening's first short side 411a<the length of a heat sink base's first short side 1bs1 (1)

The length of an opening's second short side 411b<the length of a heat sink base's second short side 1bs2 (2)

The length of an opening's first long side 412a<the length of a heat sink base's first long side 1bl1 (3)

The length of an opening's second long side 412b<the length of a heat sink base's second long side 1bl2 (4)

When the conditions expressed by the above Formulas (1) to (4) are satisfied, as illustrated in FIG. 20, the heat sink bases 1b can be screwed to the housing 40 by the power module fixing screws 72 in four regions between the corners of each of the heat sink bases 1b and the corners of each of the openings 41 in the in-plane direction of the heat sink bases 1b.

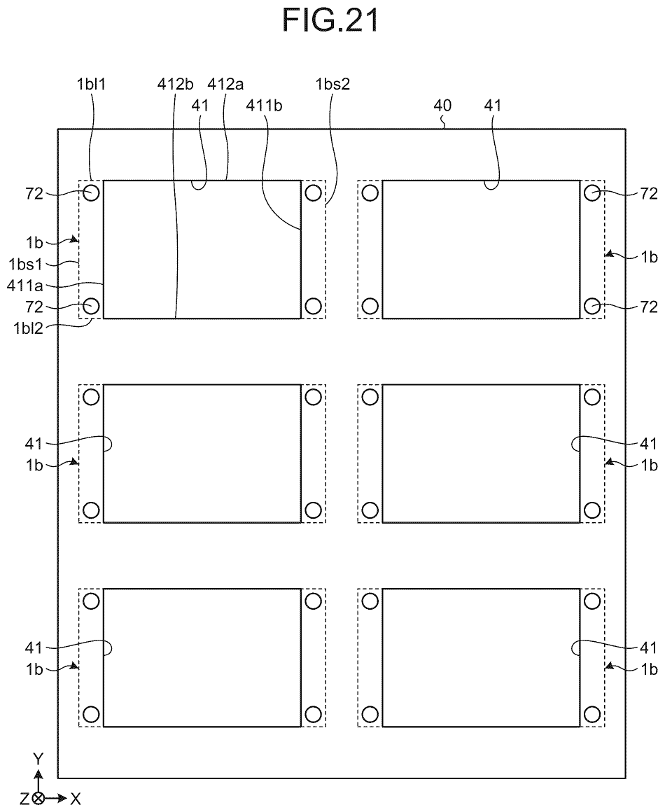

FIG. 21 is a second schematic diagram for explaining an example of the size relationship between the opening 41 of the housing 40 and the heat sink base 1b of the heat sink integrated power module 20 in the power semiconductor device 100 according to the first embodiment. In FIG. 21, in a top view of the housing 40, the positions of the heat sink bases 1b of the heat sink integrated power modules 20 mounted to the housing 40 are indicated by broken lines. In the power semiconductor device 100, when conditions expressed by the following Formulas (5) and (6) are satisfied in the in-plane direction of the housing 40 as well, the heat sink integrated power modules 20 and the housing 40 can be fixed by screwing the heat sink bases 1b and the housing 40.

The length of the opening's first long side 412a<the length of the heat sink base's first long side 1bl1 (5)

The length of the opening's second long side 412b<the length of the heat sink base's second long side 1bl2 (6)

When the conditions expressed by the above Formulas (5) and (6) are satisfied, the heat sink bases 1b can be screwed to the housing 40 by the power module fixing screws 72 in regions around four corners of each of the heat sink bases 1b in the in-plane direction of the heat sink bases 1b. In this case, as illustrated in FIG. 21, in the regions around the four corners of each of the heat sink bases 1b, the power module fixing screws 72 can be screwed in the two regions between the opening's first short side 411a and the heat sink base's first short side 1bs1 and the two regions between the opening's second short side 411b and the heat sink base's second short side 1bs2.

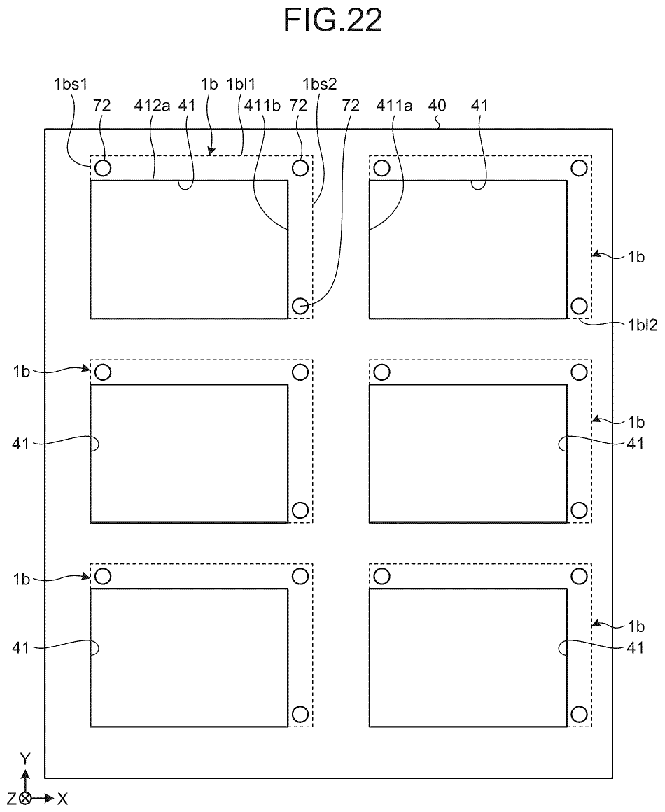

FIG. 22 is a third schematic diagram for explaining an example of the size relationship between the opening 41 of the housing 40 and the heat sink base 1b of the heat sink integrated power module 20 in the power semiconductor device 100 according to the first embodiment. In FIG. 22, in a top view of the housing 40, the positions of the heat sink bases 1b of the heat sink integrated power modules 20 mounted to the housing 40 are indicated by broken lines. In the power semiconductor device 100, when conditions expressed by the following Formulas (7) and (8) are satisfied in the in-plane direction of the housing 40 as well, the heat sink integrated power modules 20 and the housing 40 can be fixed by screwing the heat sink bases 1b and the housing 40.

The length of the opening's first short side 411a<the length of the heat sink base's first short side 1bs1 (7)

The length of the opening's first long side 412a<the length of the heat sink base's first long side 1bl1 (8)

When the conditions expressed by the above Formulas (7) and (8) are satisfied, the heat sink bases 1b can be screwed to the housing 40 by the power module fixing screws 72 in regions around four corners of each of the heat sink bases 1b in the in-plane direction of the heat sink bases 1b. In this case, as illustrated in FIG. 22, in the regions around three corners of each of the heat sink bases 1b, the power module fixing screws 72 can be screwed in the two regions between the corners of the heat sink base 1b and the corners of the opening 41 and the one region between the opening's second short side 411b and the heat sink base's second short side 1bs2.

In the power semiconductor device 100, considering that the heat sink bases 1b of the heat sink integrated power modules 20 and the housing 40 can have warpage in manufacturing and that the load of the plurality of parts connected in the heat sink integrated power modules 20 is received by the housing 40, in terms of the vibration resistance of the power semiconductor device 100 after the plurality of parts is assembled, the vibration resistance of the power semiconductor device 100 increases in the order of the example of the screwing structure illustrated in FIG. 22, the example of the screwing structure illustrated in FIG. 21, and the example of the screwing structure illustrated in FIG. 20.

Since the heat dissipation fins 1a of the heat sink integrated power modules 20 are inserted into the housing 40, a condition expressed by the following Formula (9) is satisfied in a depth direction, that is, the air inflow direction.

The lengths in the depth direction of the heat dissipation fins 1a<the length of the opening's short side 411 (9)

Moreover, since the heat dissipation fins 1a of the heat sink integrated power modules 20 are inserted into the housing 40, a condition expressed by the following Formula (10) is satisfied in the left-right direction, that is, the width direction of the power semiconductor device 100.

The distance from the leftmost heat dissipation fin 1a to the rightmost heat dissipation fin 1a<the length of the opening's long side 412 (10)

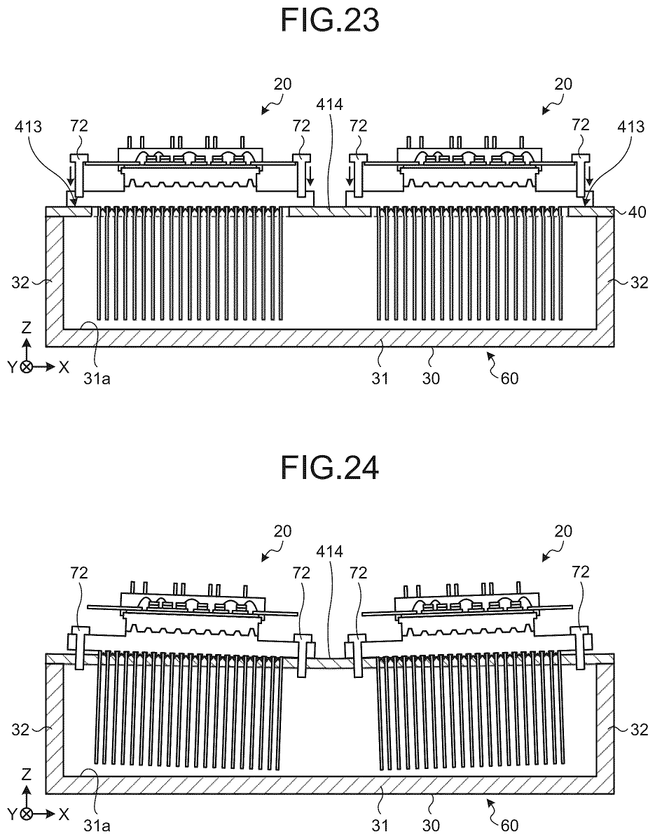

Next, effects in the structural aspect of the power semiconductor device 100 described above will be described. FIG. 23 is a first cross-sectional view illustrating a method of manufacturing a power semiconductor device of a comparative example according to the first embodiment. FIG. 24 is a second cross-sectional view illustrating the method of manufacturing the power semiconductor device of the comparative example according to the first embodiment. FIGS. 23 and 24 illustrate the cross sections at the locations where the power module fixing screws 72 are screwed. The power semiconductor device of the comparative example has the same structure as the power semiconductor device 100 except that the holding portion 60 does not include the structural support 50. In FIG. 23, the same components as those of the power semiconductor device 100 according to the first embodiment are denoted by the same reference numerals as those of the corresponding components of the power semiconductor device 100.

Also in the power semiconductor device of the comparative example, the power module fixing screws 72 are screwed in the direction indicated by arrows in FIG. 23, so that the heat sink bases 1b and the housing 40 are fixed using the power module fixing screws 72. In this case, when the power module fixing screws 72 are screwed in the center region 414 of the housing 40, the load of fastening of the power module fixing screws 72 is applied to the housing 40 via the heat sink bases 1b. Therefore, in the case where the structural support 50 is not provided in the holding portion 60, the housing 40 may be bent as illustrated in FIG. 24 by the load applied by fastening of the power module fixing screws 72. When the housing 40 is bent, the heat sink integrated power modules 20 may not be fixed to the housing 40.

Even when the heat sink integrated power modules 20 are successfully fixed to the housing 40 with the housing 40 being bent, a finished product in which the other parts are attached to the heat sink integrated power modules 20 may have reduced vibration resistance, and cyclic fatigue caused by vibration applied to the power semiconductor device of the comparative example may damage the screw fastening portions such as the housing fixing screws 71 and the power module fixing screws 72, and damage the screw fastening portions and components around the screw fastening portions.

In order to solve the above problem, it is necessary to increase the rigidity of the housing 40, specifically, to increase the thickness of the housing 40. When the thickness of the housing 40 is increased, the weight of the power semiconductor device increases, which hinders the reduction in weight of the power semiconductor device.

On the other hand, in the power semiconductor device 100 according to the first embodiment, the structural support 50 is provided in the region corresponding to the center region 414 of the housing 40 in the holding portion 60. That is, in the power semiconductor device 100, the structural support 50 is attached and fixed to the inner surface 31a of the bottom surface portion 31 of the outer frame 30. As a result, in the power semiconductor device 100, the structural support 50 can receive the load at the time of fixing the heat sink integrated power modules 20 to the housing 40 by fastening the power module fixing screws 72 in the center region 414 of the housing 40. In the finished product in which the other parts are attached to the heat sink integrated power modules 20, the structural support 50 can also receive the load when vibration is applied to the power semiconductor device 100. Therefore, the power semiconductor device 100 can realize a power semiconductor device having high productivity and high vibration resistance.

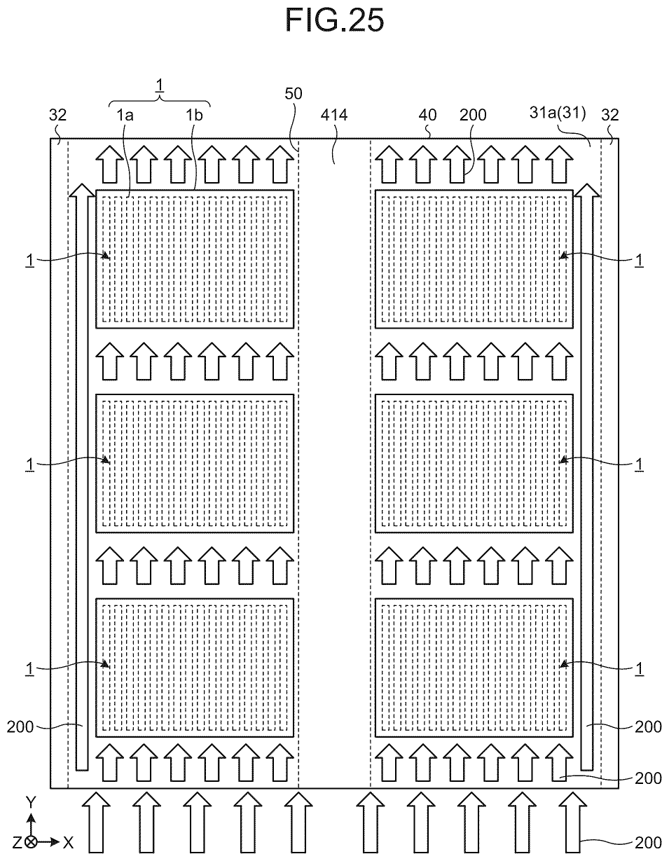

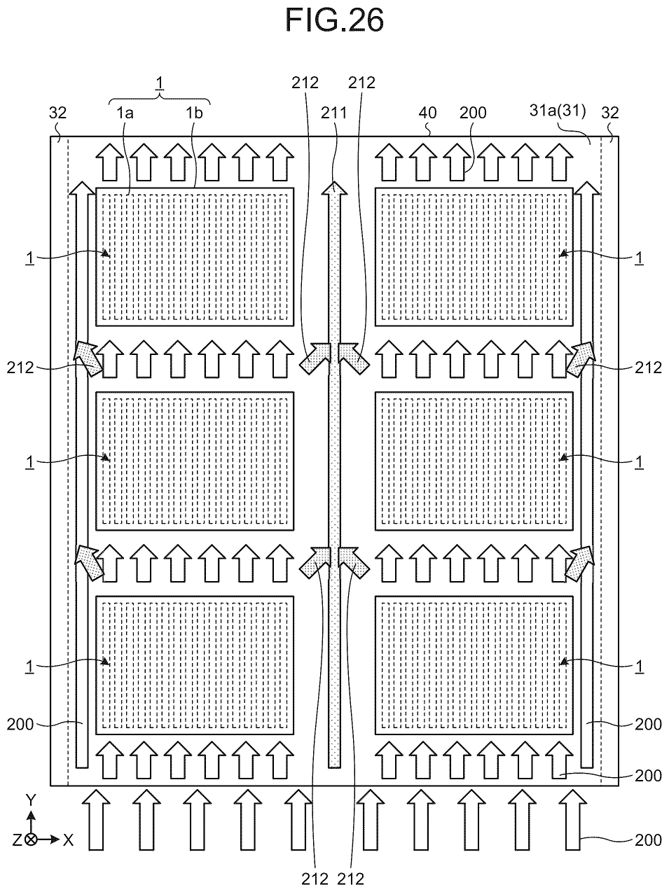

Next, effects in the aspect of heat dissipation performance of the power semiconductor device 100 described above will be described. FIG. 25 is a schematic diagram for explaining an airflow inside the holding portion 60 of the power semiconductor device 100 according to the first embodiment. FIG. 26 is a schematic diagram for explaining an airflow inside the holding portion 60 of a power semiconductor device of a comparative example according to the first embodiment. FIGS. 25 and 26 illustrate a state in which a part of the power semiconductor device is seen through. In the power semiconductor device of the comparative example, as with the power semiconductor device 100, the air flow 200 blown from the blowing system to the power semiconductor device 100 flows around the heat dissipation fins 1a of the heat sinks 1 inside the holding portion 60, so that the heat generated in the semiconductor elements 5 of the power modules 11 is dissipated by the heat dissipation fins 1a in an accelerated manner.

However, in the power semiconductor device of the comparative example, since the structural support 50 is not provided in the region corresponding to the center region 414 of the housing 40, as illustrated in FIG. 26, a first airflow vector 211 having a relatively large air volume and not contributing to heat dissipation in the heat dissipation fins 1a occurs in the region corresponding to the center region 414 of the housing 40. When the first airflow vector 211 occurs, the airflow inside the holding portion 60 is disturbed, and second airflow vectors 212 not contributing to heat dissipation in the heat dissipation fins 1a occur in the region corresponding to the center region 414 of the housing 40 inside the holding portion 60 and the regions corresponding to the end regions 415 of the housing 40 inside the holding portion 60. In this case, the flow rate of the air flow flowing between the adjacent heat dissipation fins 1a decreases, which decreases a heat transfer rate between the heat dissipation fins 1a from between the heat dissipation fins 1a to the air around the heat dissipation fins 1a, and decreases the heat dissipation performance of the heat sinks 1.

On the other hand, in the power semiconductor device 100 in which the structural support 50 is provided in the region corresponding to the center region 414 of the housing 40, as illustrated in FIG. 25, the first airflow vector 211 and the second airflow vectors 212 not contributing to heat dissipation in the heat dissipation fins 1a as described above do not occur. Therefore, in the power semiconductor device 100, the air flow 200 that is rectified flows between the heat dissipation fins 1a adjacent to each other, so that the heat dissipation performance of the heat dissipation fins 1a as designed can be achieved.

In the power semiconductor device 100 described above, the plurality of the heat sink integrated power modules 20 having high heat dissipation performance is used, so that a power semiconductor device having a large power capacity can be realized with high productivity as compared to a power semiconductor device having a structure in which a plurality of power modules is fixed to one heat sink using thermal conductive grease and a power semiconductor device having a structure in which singulated heat sinks and one power module are fixed using thermal conductive grease. Moreover, in the power semiconductor device 100 not using thermal conductive grease, when the heat sink integrated power module 20 is replaced, processing such as removal and rearrangement of the thermal conductive grease is unnecessary, and the heat sink integrated power module 20 can be replaced only by attaching and detaching the screws, which results in good productivity and maintainability.

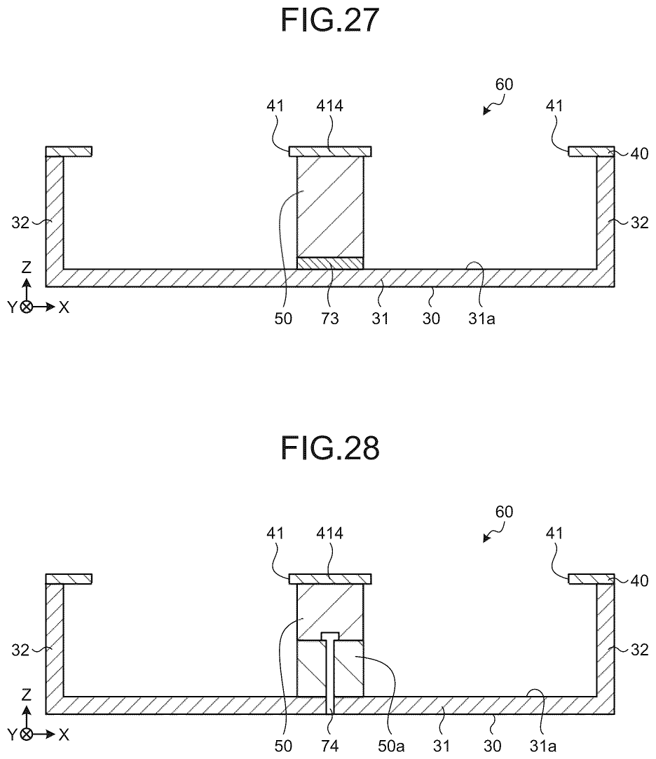

Next, a method of fixing the structural support 50 to the outer frame 30 will be described. FIG. 27 is a first cross-sectional view illustrating an example of the method of fixing the structural support 50 to the outer frame 30 of the power semiconductor device 100 according to the first embodiment. FIG. 28 is a second cross-sectional view illustrating an example of the method of fixing the structural support 50 to the outer frame 30 of the power semiconductor device 100 according to the first embodiment.

In the example illustrated in FIG. 27, the structural support 50 is fixed to the inner surface 31a of the bottom surface portion 31 of the outer frame 30 by a weld 73. In the example illustrated in FIG. 28, the structural support 50 is fixed to the inner surface 31a of the bottom surface portion 31 of the outer frame 30 by a structural support fixing screw 74. Note that the method of fixing the structural support 50 to the outer frame 30 is not limited to the above examples, and any method such as fixing the structural support 50 to the outer frame 30 with an adhesive can be applied as long as the method can fix the structural support 50 to the outer frame 30.

The example illustrated in FIG. 28 illustrates the cross section at the location where the structural support fixing screw 74 is fastened. FIG. 28 illustrates the example in which, in the structural support 50, a screw fixing region 50a is provided in a partial region in the longitudinal direction of the structural support 50. The screw fixing region 50a is a region for fixing the structural support 50 to the inner surface 31a of the bottom surface portion 31 of the outer frame 30 by the structural support fixing screw 74.

The screw fixing region 50a can be provided at any position in the longitudinal direction of the structural support 50 as long as the structural support 50 can be fixed to the outer frame 30 by the structural support fixing screw 74. Moreover, the screw fixing region 50a can be provided in any number as long as the structural support 50 can be fixed to the outer frame 30 by the structural support fixing screw 74. The screw fixing region 50a may be provided at, for example, one position in a central portion in the longitudinal direction of the structural support 50, or may be provided at, for example, two positions on both end sides in the longitudinal direction of the structural support 50.

The height of the screw fixing region 50a can be set to any height as long as the structural support 50 can be fixed to the outer frame 30 by the structural support fixing screw 74. In the example illustrated in FIG. 28, the height of the screw fixing region 50a is half the height of the other region of the structural support 50 outside the screw fixing region 50a. Alternatively, the height of the screw fixing region 50a may be the same as the height of the other region of the structural support 50 outside the screw fixing region 50a. In this case, the center region 414 of the housing 40 is not provided in a region corresponding to an upper portion of the screw fixing region 50a.

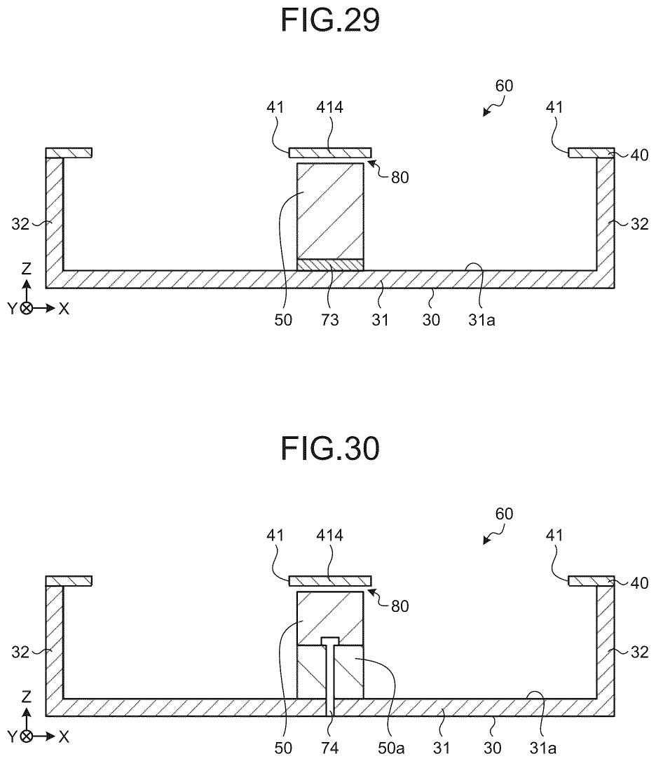

FIG. 29 is a third cross-sectional view illustrating an example of the method of fixing the structural support 50 to the outer frame 30 of the power semiconductor device 100 according to the first embodiment. FIG. 30 is a fourth cross-sectional view illustrating an example of the method of fixing the structural support 50 to the outer frame 30 of the power semiconductor device 100 according to the first embodiment. FIG. 29 is the view corresponding to FIG. 27, and the structural support 50 is fixed to the inner surface 31a of the bottom surface portion 31 of the outer frame 30 by the weld 73. FIG. 30 is the view corresponding to FIG. 28, and the structural support 50 is fixed to the inner surface 31a of the bottom surface portion 31 of the outer frame 30 by the structural support fixing screw 74.

Considering dimensional variations and assembly tolerances in the manufacture of each part constituting the holding portion 60, as illustrated in FIGS. 29 and 30, there is a possibility that the center region 414 of the housing 40 and an upper surface of the structural support 50 are not in contact with each other, and that a gap 80 is formed between the center region 414 of the housing 40 and the upper surface of the structural support 50. In this case, when the heat sink integrated power modules 20 and the housing 40 are fixed using the power module fixing screws 72, the housing 40 is deformed by fastening of the power module fixing screws 72, so that the center region 414 of the housing 40 and the upper surface of the structural support 50 come into contact with each other. With the center region 414 of the housing 40 and the upper surface of the structural support 50 being in contact with each other, the structural support 50 can receive the load at the time of fixing the heat sink integrated power modules 20 to the housing 40.

Therefore, as illustrated in FIG. 29, even when the gap 80 is formed between the center region 414 of the housing 40 and the upper surface of the structural support 50, the deformation of the housing 40 at the time of fastening the power module fixing screws 72 can be reduced by the structural support 50 provided in the holding portion 60. As a result, the power semiconductor device 100 can prevent bending of the housing 40 at the time of fastening of the power module fixing screws 72, can reduce the incidence of failure at the time of fixing the heat sink integrated power modules 20 to the housing 40, and can improve productivity. Furthermore, regarding the vibration resistance of the finished product in which the other parts are attached to the heat sink integrated power modules 20, deformation of the housing 40 when vibration is applied to the power semiconductor device 100 can be prevented or controlled. Therefore, the vibration resistance of the product is improved.

As described above, even in the state where the housing 40 and the structural support 50 are not in contact with each other, that is, even in the case where the gap 80 is formed between the center region 414 of the housing 40 and the upper surface of the structural support 50, the power semiconductor device 100 can obtain an effect similar to that of the case where the gap 80 is not formed between the center region 414 of the housing 40 and the upper surface of the structural support 50.

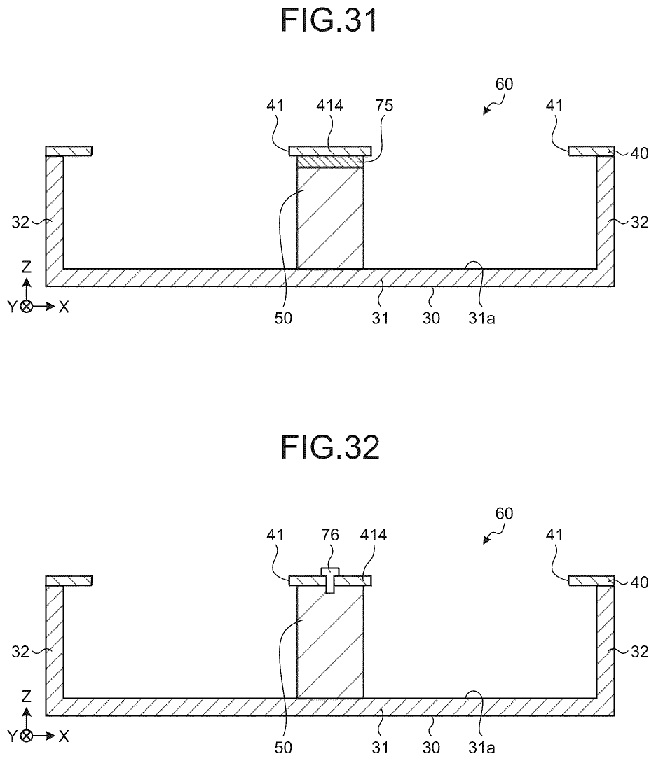

The description has been made of the structure of the power semiconductor device 100 in which the structural support 50 is fixed to the outer frame 30 and the housing 40 is fixed to the outer frame 30, but even in a case where the structural support 50 is fixed to the housing 40, an effect similar to that described above can be obtained. FIG. 31 is a first cross-sectional view illustrating an example of a method of fixing the structural support 50 to the housing 40 of the power semiconductor device 100 according to the first embodiment. FIG. 32 is a second cross-sectional view illustrating an example of the method of fixing the structural support 50 to the housing 40 of the power semiconductor device 100 according to the first embodiment.

In the example illustrated in FIG. 31, an upper surface of the structural support 50 is fixed to the center region 414 of the housing 40 by a weld 75, and a lower surface of the structural support 50 is in contact with the inner surface 31a of the bottom surface portion 31 of the outer frame 30. In the example illustrated in FIG. 32, the structural support 50 is fixed to the center region 414 of the housing 40 by a structural support fixing screw 76, and the lower surface of the structural support 50 is in contact with the inner surface 31a of the bottom surface portion 31 of the outer frame 30. Note that the method of fixing the structural support 50 to the housing 40 is not limited to the above examples, and any method such as fixing the structural support 50 to the housing 40 with an adhesive can be applied as long as the method can fix the structural support 50 to the housing 40.

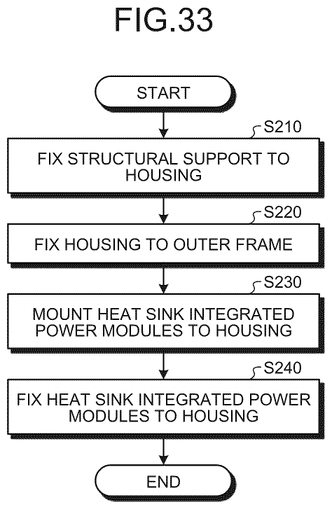

FIG. 33 is a flowchart illustrating a procedure of another method of manufacturing the power semiconductor device 100 according to the first embodiment. Here, a description will be made of a method of manufacturing the power semiconductor device 100 in a case where the structural support 50 is fixed to the housing 40.

First, in step S210, the structural support 50 is attached and fixed to the housing 40. As described above, the structural support 50 is fixed to the housing 40 by the weld 75 or the structural support fixing screw 76.

Next, in step S220, as in the case of step S120, the housing 40 is screwed and fixed to the outer frame 30 using the housing fixing screws 71.

Next, in step S230, as in the case of step S130, the heat sink integrated power modules 20 are mounted to the housing 40.

Next, in step S240, as in the case of step S140, the heat sink integrated power modules 20 are screwed and fixed to the housing 40.

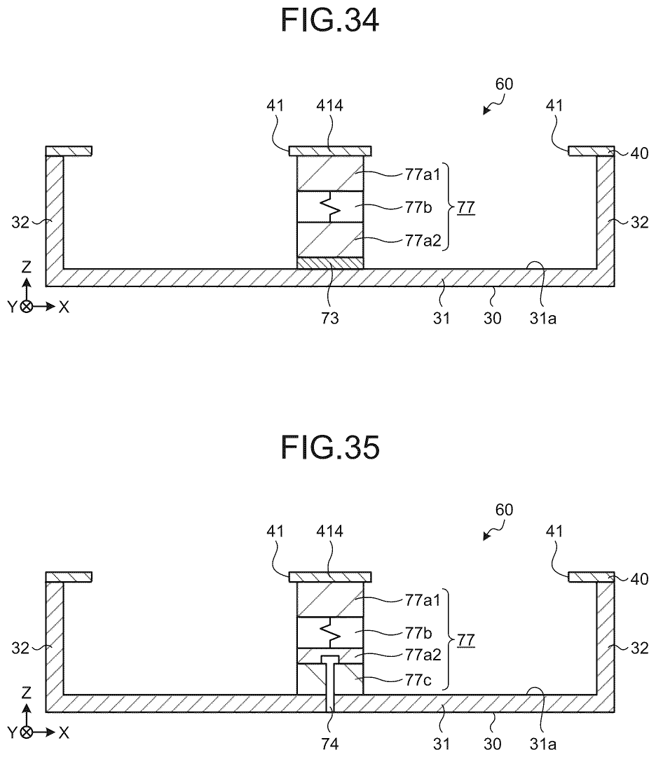

FIG. 34 is a first cross-sectional view illustrating a structure of the power semiconductor device 100 in a case where an elastic structural support 77 is applied to the power semiconductor device 100 according to the first embodiment. FIG. 35 is a second cross-sectional view illustrating a structure of the power semiconductor device 100 in a case where the elastic structural support 77 is applied to the power semiconductor device 100 according to the first embodiment. In order to fix the housing 40 and the structural support 50 with the housing 40 and the structural support 50 being securely in contact with each other, the elastic structural support 77 can be used as illustrated in FIGS. 34 and 35.

The elastic structural support 77 is a structural support having elasticity. Therefore, with the use of the elastic structural support 77 for fixing the housing 40 and the structural support 50, even in a case where dimensional variations or assembly tolerances occur in the manufacture of each part constituting the holding portion 60, the elasticity of the elastic structural support 77 absorbs the dimensional variations and assembly tolerances in the manufacture of each part. As a result, in the power semiconductor device 100, the housing 40 and the structural support 50 can be fixed while being securely in contact with each other. The power semiconductor device 100 uses the elastic structural support 77 to be able to more stably improve the vibration resistance.

In the examples illustrated in FIGS. 34 and 35, the elastic structural support 77 has a structure in which the structural support is divided into two divided portions, that is, a first divided structural support 77a1 and a second divided structural support 77a2, and a coil spring 77b is inserted between the first divided structural support 77a1 and the second divided structural support 77a2. The first divided structural support 77a1 is disposed on the side of the center region 414 of the housing 40 in the height direction. The second divided structural support 77a2 is disposed on the side of the bottom surface portion 31 of the outer frame 30 in the height direction.

Moreover, in the elastic structural support 77 in the example illustrated in FIG. 34, the second divided structural support 77a2 disposed on the side of the bottom surface portion 31 of the outer frame 30 in the height direction is fixed to the inner surface 31a of the bottom surface portion 31 of the outer frame 30 by the weld 73. On the other hand, in the elastic structural support 77 in the example illustrated in FIG. 35, the second divided structural support 77a2 disposed on the side of the bottom surface portion 31 of the outer frame 30 in the height direction is fixed to the inner surface 31a of the bottom surface portion 31 of the outer frame 30 by the structural support fixing screw 74.

The example illustrated in FIG. 35 illustrates the cross section at the location where the structural support fixing screw 74 is fastened. FIG. 35 illustrates the example in which the second divided structural support 77a2 is provided with a screw fixing region 77c in a partial region in the longitudinal direction of the second divided structural support 77a2. The longitudinal direction of the second divided structural support 77a2 can be rephrased as the longitudinal direction of the elastic structural support 77. The screw fixing region 77c is a region for fixing the second divided structural support 77a2 to the inner surface 31a of the bottom surface portion 31 of the outer frame 30 by the structural support fixing screw 74. The coil spring 77b and the first divided structural support 77a1 are not disposed in an upper portion of the screw fixing region 77c in the height direction.

The screw fixing region 77c can be provided at any position in the longitudinal direction of the second divided structural support 77a2 as long as the second divided structural support 77a2 can be fixed to the outer frame 30 by the structural support fixing screw 74. Moreover, the screw fixing region 77c can be provided in any number as long as the second divided structural support 77a2 can be fixed to the outer frame 30 by the structural support fixing screw 74. The screw fixing region 77c may be provided at, for example, one position in a central portion in the longitudinal direction of the second divided structural support 77a2, or may be provided at, for example, two positions on both end sides in the longitudinal direction of the second divided structural support 77a2.

The height of the screw fixing region 77c can be set to any height as long as the second divided structural support 77a2 can be fixed to the outer frame 30 by the structural support fixing screw 74. In the example illustrated in FIG. 35, the height of the screw fixing region 77c is one-third of the height of the other region of the second divided structural support 77a2 outside the screw fixing region 77c. Alternatively, the height of the screw fixing region 77c may be the same as the height of the other region of the second divided structural support 77a2 outside the screw fixing region 77c.

Note that the structure of the elastic structural support 77 is not limited to the above examples. For example, even in a case where the power semiconductor device 100 has a configuration in which a sponge having an elastic function is sandwiched at least either between the inner surface 31a of the bottom surface portion 31 of the outer frame 30 and the structural support 50 or between the center region 414 of the housing 40 and the structural support 50, an effect similar to that described above can be obtained.

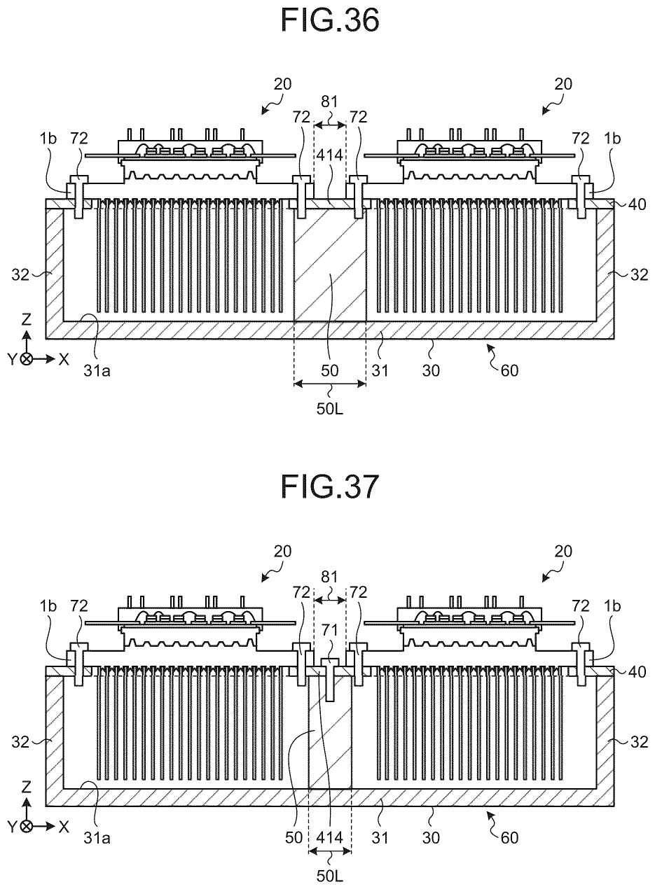

Next, a positional relationship among the structural support 50, the heat sink bases 1b of the heat sink integrated power modules 20, and the housing 40 will be described. FIG. 36 is a first cross-sectional view for explaining the positional relationship among the structural support 50, the heat sink bases 1b of the heat sink integrated power modules, and the housing 40 in the power semiconductor device 100 according to the first embodiment.

Focusing on the screw fastening portions in the power semiconductor device 100, as illustrated in FIG. 36, a structural support width dimension 50L, which is a dimension of the width of the structural support 50, is preferably larger than a dimension of a gap 81 between the heat sink bases 1b of the heat sink integrated power modules 20 adjacent to each other in the left-right direction. The structural support width dimension 50L is the dimension that allows the power module fixing screws 72 to be fastened in the center region 414 of the housing 40.

Then, the heat sink bases 1b of the heat sink integrated power modules 20 adjacent to each other in the left-right direction are mounted on the housing 40. In this state, the heat sink bases 1b and the housing 40 are fixed by the power module fixing screws 72 in the end regions 415 of the housing 40. Moreover, the power module fixing screws 72 are fastened from above the center region 414 of the housing 40, so that the heat sink bases 1b, the housing 40, and the structural support 50 are fixed by the power module fixing screws 72.

As a result, the heat sink integrated power modules 29 are firmly fixed to the holding portion 60, and the structure of the power semiconductor device 100 having higher vibration resistance can be obtained. That is, with the above structure, a cross-sectional area of an air passage along an XZ plane inside the holding portion 60 is reduced, the flow rate of the air flow between the heat dissipation fins 1a adjacent to each other is increased, the heat transfer rate from between the heat dissipation fins 1a to the air around the heat dissipation fins 1a is increased, and the heat dissipation performance of the heat sinks 1 is maximized.

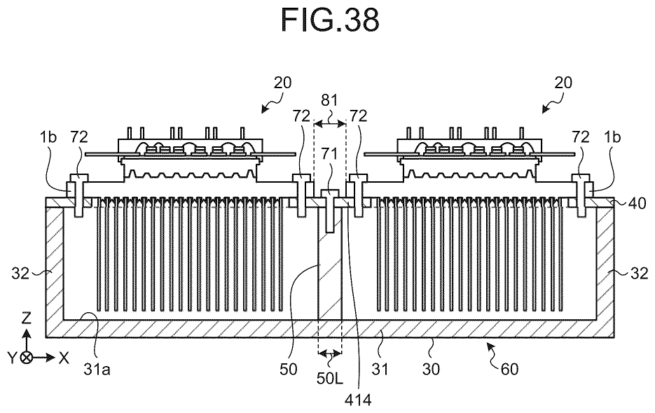

FIG. 37 is a second cross-sectional view for explaining the relationship among the structural support 50, the heat sink bases 1b of the heat sink integrated power modules, and the housing 40 in the power semiconductor device 100 according to the first embodiment. FIG. 38 is a third cross-sectional view for explaining the relationship among the structural support 50, the heat sink bases 1b of the heat sink integrated power modules, and the housing 40 in the power semiconductor device 100 according to the first embodiment.

In the structure illustrated in FIG. 37, the structural support width dimension 50L is larger than the dimension of the gap 81 between the heat sink bases 1b of the heat sink integrated power modules 20 adjacent to each other in the left-right direction. In the structure illustrated in FIG. 38, the structural support width dimension 50L is smaller than the dimension of the gap 81 between the heat sink bases 1b of the heat sink integrated power modules 20 adjacent to each other in the left-right direction. The gap 81 has the dimension that allows for fastening of the housing fixing screw 71 in the center region 414 of the housing 40.

Both in the structure illustrated in FIG. 37 and the structure illustrated in FIG. 38, the housing fixing screw 71 is fastened from above the center region 414 of the housing 40, so that the housing 40 and the structural support 50 are fixed by the housing fixing screw 71. With the structure illustrated in FIG. 37 and the structure illustrated in FIG. 38, it is possible to obtain the structure of the power semiconductor device 100 having high vibration resistance while securing the fixing strength of the holding portion 60. Note that the vibration resistance of the power semiconductor device 100 increases in the order of the structure illustrated in FIG. 38, the structure illustrated in FIG. 37, and the structure illustrated in FIG. 36.

Moreover, in the structure illustrated in FIG. 36, as compared with the structure illustrated in FIG. 37 and the structure illustrated in FIG. 38, the number of screws used can be reduced so that the productivity of the power semiconductor device 100 can be improved and that the manufacturing cost of the power semiconductor device 100 can be reduced.

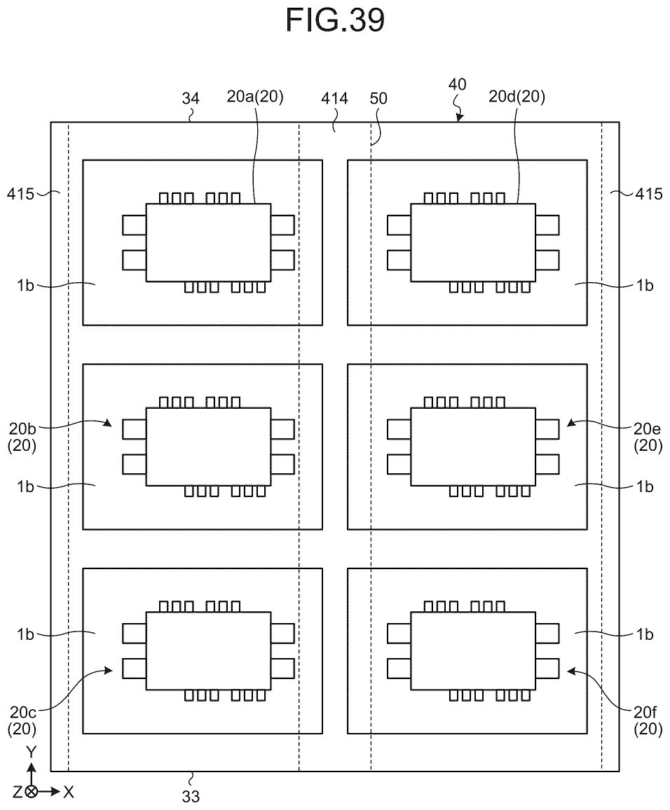

Next, the shape and arrangement of the structural support 50 will be described. FIG. 39 is a first top view for explaining the shape and arrangement of the structural support 50 in the power semiconductor device 100 according to the first embodiment. In FIG. 39, a part of the configuration of the power semiconductor device 100 is omitted. In the structural support 50 having the structure illustrated in FIG. 39, in the in-plane direction of the bottom surface portion 31 of the outer frame 30 and in the in-plane direction of the housing 40, the longitudinal direction of the structural support 50 is parallel to the depth direction of the power semiconductor device 100, that is, the direction of travel of the air flow 200 inside the holding portion 60. Moreover, the structural support 50 continuously extends from a front side end 33 of the outer frame 30 to a back side end 34 of the outer frame 30. That is, the structural support 50 extends continuously in the direction from the inlet toward the outlet in the region from the inlet of the air to the outlet of the air in the holding portion 60. Note that the shape and arrangement of the structural support 50 are not limited to the structure illustrated in FIG. 39.

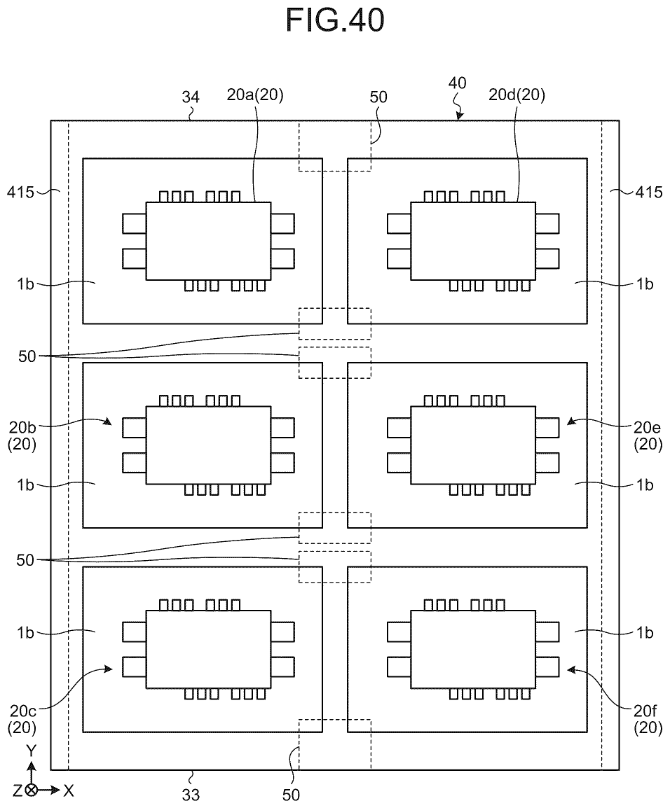

FIG. 40 is a second top view for explaining the shape and arrangement of the structural support 50 in the power semiconductor device 100 according to the first embodiment. In FIG. 40, a part of the configuration of the power semiconductor device 100 is omitted. In the structure illustrated in FIG. 40, in the in-plane direction of the bottom surface portion 31 of the outer frame 30 and the in-plane direction of the housing 40, the structural supports 50 are partially disposed in some regions on a windward side of the direction of travel of the air flow 200 flowing through the holding portion 60, the regions including adjacent corners of the heat sink bases 1b of two of the heat sink integrated power modules 20 adjacent to each other in the left-right direction. Also, in the in-plane direction of the bottom surface portion 31 of the outer frame 30 and the in-plane direction of the housing 40, the structural supports 50 are partially disposed in some regions on a leeward side of the direction of travel of the air flow 200 flowing through the holding portion 60, the regions including adjacent corners of the heat sink bases 1b of two of the heat sink integrated power modules 20 adjacent to each other in the left-right direction. That is, the structural supports 50 are discontinuously disposed in the direction from the inlet toward the outlet in the region from the inlet of the air to the outlet of the air in the holding portion 60.

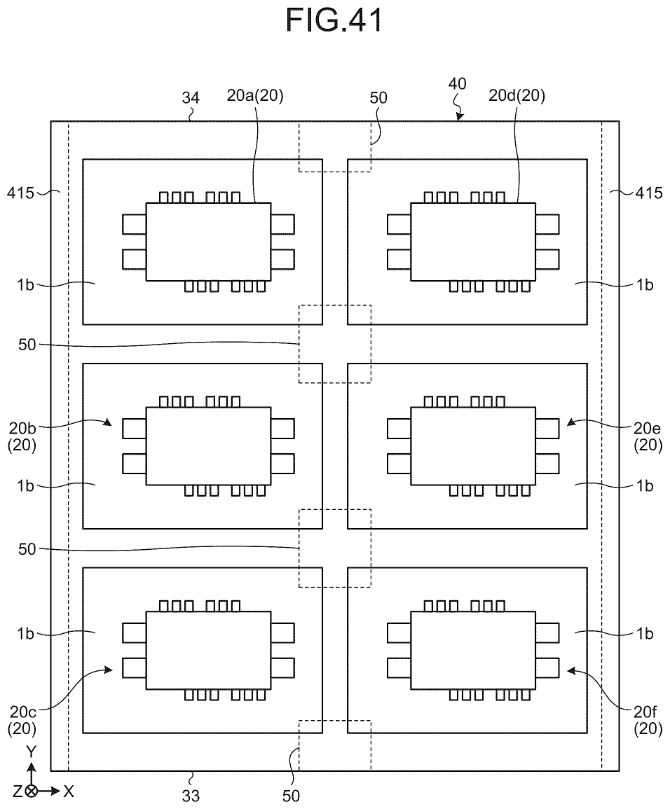

FIG. 41 is a third top view for explaining the shape and arrangement of the structural support 50 in the power semiconductor device 100 according to the first embodiment. In FIG. 41, a part of the configuration of the power semiconductor device 100 is omitted. In the structure illustrated in FIG. 41, in the in-plane direction of the bottom surface portion 31 of the outer frame 30 and the in-plane direction of the housing 40, the structural support 50 is partially disposed in a partial region on the windward side of the direction of travel of the air flow 200 flowing through the holding portion 60, the region including adjacent corners of the heat sink bases 1b of two of the heat sink integrated power modules 20 that are on the windward side and adjacent to each other in the left-right direction. Also, in the in-plane direction of the bottom surface portion 31 of the outer frame 30 and the in-plane direction of the housing 40, the structural support 50 is partially disposed in a partial region on the leeward side of the direction of travel of the air flow 200 flowing through the holding portion 60, the region including adjacent corners of the heat sink bases 1b of two of the heat sink integrated power modules 20 that are on the leeward side and adjacent to each other in the left-right direction. Moreover, in the in-plane direction of the bottom surface portion 31 of the outer frame 30 and the in-plane direction of the housing 40, the structural supports 50 are partially disposed in some regions including adjacent corners of the heat sink bases 1b of four of the heat sink integrated power modules 20 adjacent to one another. That is, the structural supports 50 are discontinuously disposed in the direction from the inlet toward the outlet in the region from the inlet of the air to the outlet of the air in the holding portion 60.

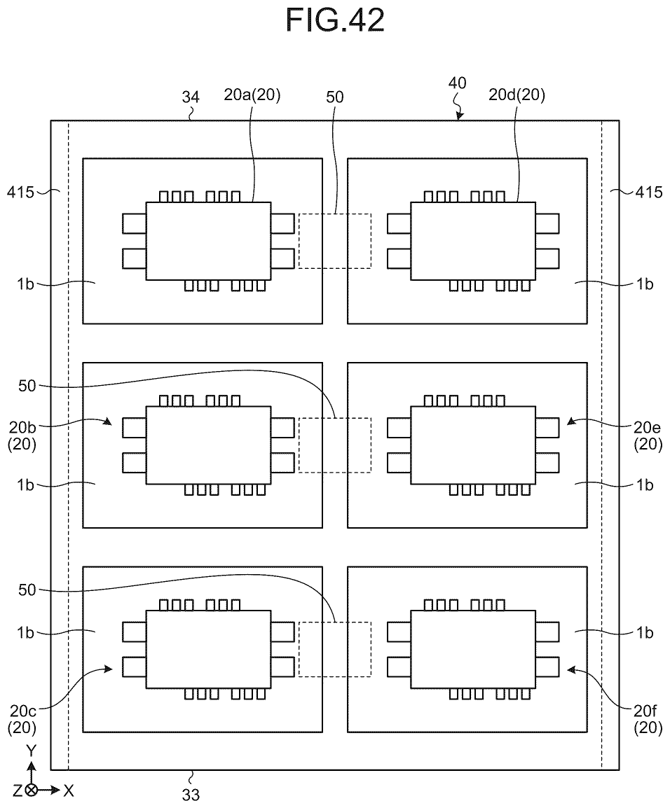

FIG. 42 is a fourth top view for explaining the shape and arrangement of the structural support 50 in the power semiconductor device 100 according to the first embodiment. In FIG. 42, a part of the configuration of the power semiconductor device 100 is omitted. In the structure illustrated in FIG. 42, in the in-plane direction of the bottom surface portion 31 of the outer frame 30 and the in-plane direction of the housing 40, the structural supports 50 are partially disposed in some regions of the heat sink bases 1b of two of the heat sink integrated power modules 20 adjacent to each other in the left-right direction, the regions including the center region in the depth direction.

With the structures illustrated in FIGS. 39 to 42, the power semiconductor device 100 having high vibration resistance as described above is obtained. Moreover, in the power semiconductor device 100, the structural support 50 is disposed on the windward side of the air flow 200 in the holding portion 60, so that the air flow 200 blown from the blowing system can flow between the adjacent heat dissipation fins 1a while being rectified. As a result, the power semiconductor device 100 can obtain the heat dissipation performance as designed. Note that the effect of the vibration resistance of the power semiconductor device 100 by the above structures increases in the order of the structure illustrated in FIG. 42, the structure illustrated in FIG. 41, the structure illustrated in FIG. 40, and the structure illustrated in FIG. 39.

As described above, in the power semiconductor device 100 according to the first embodiment, the structural support 50 is disposed on the bottom surface portion 31 of the outer frame 30 of the holding portion 60 so as to receive the loads of the plurality of the heat sink integrated power modules 20 and the housing 40 to which the plurality of the heat sink integrated power modules 20 is mounted. Therefore, the power semiconductor device 100 can prevent bending of the housing 40 that occurs when the plurality of the heat sink integrated power modules 20 is fixed to the housing 40. As a result, the power semiconductor device 100 can reduce or prevent a decrease in the heat dissipation performance of the heat sink 1 due to a gap formed between the heat sink 1 and the housing 49 when the housing 40 is bent, and can improve the heat dissipation performance for the heat generated in the power module 11 and the vibration resistance.

Moreover, the structural support 50 is disposed in the region corresponding to the center region 414 of the housing 40 on the bottom surface portion 31 of the outer frame 30. As a result, the structural support 50 can equally receive the loads of the two heat sink integrated power modules 20 adjacent to each other in the left-right direction, so that it is possible to further prevent bending of the housing 40 that occurs when the plurality of the heat sink integrated power modules 20 is fixed to the housing 40.

Moreover, in the power semiconductor device 100, the structural support 50 is disposed on the windward side in the holding portion 60 to form an air passage for rectifying the air flow 200 flowing into the holding portion 60 and allow the rectified air to flow into the heat sink 1, so that the heat dissipation performance for the heat generated in the power module 11 is improved.

Then, according to the configuration of the power semiconductor device 100, the plurality of the heat sink integrated power modules 20 having high heat dissipation performance can be applied to a power system in a high capacity band in which a plurality of power modules is used in a state where the plurality of the heat sink integrated power modules has high heat dissipation performance and high vibration resistance.

Therefore, the power semiconductor device 100 according to the first embodiment has an effect of being able to prevent bending of the housing to which the plurality of the power modules and the heat sinks are attached.

### Second Embodiment

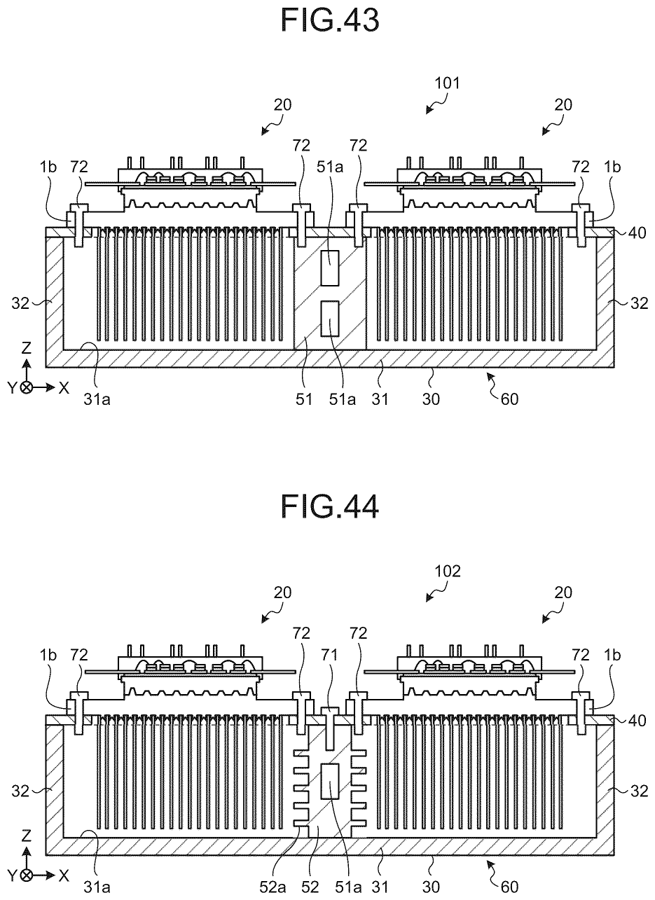

FIG. 43 is a cross-sectional view illustrating a configuration of a power semiconductor device 101 according to a second embodiment. The power semiconductor device 101 according to the second embodiment is different from the power semiconductor device 100 according to the first embodiment in that a structural support 51 is included instead of the structural support 50. The structural support 51 includes through holes 51a passing through the structural support 51 in the depth direction. That is, the structural support 51 includes the through holes 51a passing through the structural support 51 in the direction from the inlet toward the outlet of the holding portion 60. In the power semiconductor device 101, the structural support 51 includes the through holes 51a so that the surface area of the structural support 51 is increased, and thus the structural support 51 exhibits improved heat dissipation performance for the heat generated in the semiconductor elements 5 of the power modules 11.

FIG. 44 is a cross-sectional view illustrating a configuration of a power semiconductor device 102 according to the second embodiment. The power semiconductor device 102 according to the second embodiment is different from the power semiconductor device 100 according to the first embodiment in that a structural support 52 is included instead of the structural support 50. In addition to the structure of the structural support 51, the structural support 52 includes irregularities 52a on a surface of the structural support 52. In the power semiconductor device 102, the structural support 52 includes the irregularities 52a so that the surface area of the structural support 52 is increased, and thus the structural support 52 exhibits improved heat dissipation performance for the heat generated in the semiconductor elements 5 of the power modules 11.

### Third Embodiment

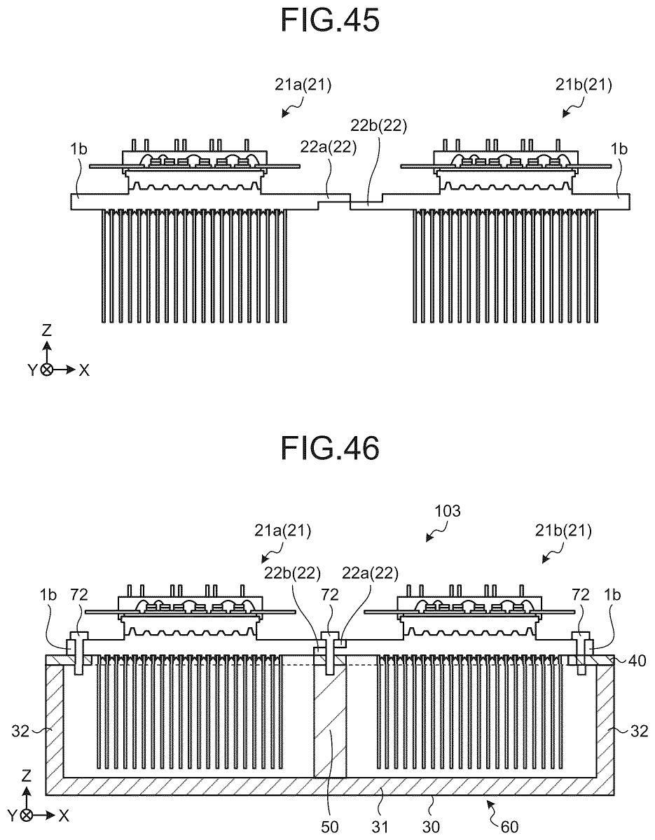

FIG. 45 is a cross-sectional view illustrating a configuration of heat sink integrated power modules 21 according to a third embodiment. FIG. 46 is a cross-sectional view illustrating a configuration of a power semiconductor device 103 according to the third embodiment.

The power semiconductor device 100 described above uses the heat sink integrated power module 20 in which one heat sink 1 is provided for one power module 11, so that handling at the time of assembling the power semiconductor device 100 and detachability of the parts at the time of maintenance are improved. On the other hand, in the power semiconductor device 100, since one heat sink 1 is singulated for one power module 11, the number of screws for fixing the heat sink integrated power modules 20 and the housing 40 is increased as compared with a case where a plurality of power modules is mounted on one heat sink, and thus the productivity may be reduced.

Therefore, as illustrated in FIG. 45, in each of the heat sink integrated power modules 21 according to the third embodiment, a protrusion 22 is provided at an end of the heat sink base 1b in the in-plane direction of the heat sink base 1b.

As illustrated in FIG. 45, in a first heat sink integrated power module 21a that is the heat sink integrated power module 21, a first protrusion 22a as the protrusion 22 is provided at the end of the heat sink base 1b in the in-plane direction of the heat sink base 1b. The first protrusion 22a is provided at the end of the heat sink base 1b on the side of another one of the power semiconductor devices 103 adjacent in the left-right direction. In addition, the first protrusion 22a is provided at an upper portion of the end of the heat sink base 1b.

As illustrated in FIG. 45, in a second heat sink integrated power module 21b that is the heat sink integrated power module 21, a second protrusion 22b as the protrusion 22 is provided at the end of the heat sink base 1b in the in-plane direction of the heat sink base 1b. The second protrusion 22b is provided at the end of the heat sink base 1b on the side of another one of the power semiconductor devices 103 adjacent in the left-right direction. In addition, the second protrusion 22b is provided at a lower portion of the end of the heat sink base 1b.

As illustrated in FIG. 46, the first heat sink integrated power module 21a and the second heat sink integrated power module 21b are mounted on the housing 40 such that the first protrusion 22a of the first heat sink integrated power module 21a and the second protrusion 22b of the second heat sink integrated power module 21b overlap each other. Then, the first protrusion 22a and the second protrusion 22b overlapping each other, the center region 414 of the housing 40, and the structural support 50 are fastened by the power module fixing screw 72, so that the first protrusion 22a, the second protrusion 22b, and the structural support 50 are fixed. That is, the first protrusion 22a, the second protrusion 22b, the center region 414 of the housing 40, and the structural support 50 are screwed while overlapping one another.

The power semiconductor device 103 adopts such a structure to be able to reduce the number of screws for fixing the heat sink integrated power modules 20 and the housing 40, whereby the productivity is improved.

Moreover, the first protrusion 22a, the second protrusion 22b, and the structural support 50 are fixed with one power module fixing screw 72, so that a region where the first heat sink integrated power module 21a, the second heat sink integrated power module 21b, and the structural support 50 are fixed in the center region 414 of the housing 40 can be narrowed in the left-right direction. As a result, the number of the heat dissipation fins 1a provided in the heat sink base 1b can be increased. Therefore, in the power semiconductor device 103, the heat sink 1 has improved heat dissipation performance for the heat generated in the semiconductor element 5 of the power module 11.

The configurations illustrated in the above embodiments each illustrate an example so that another known technique can be combined, the embodiments can be combined together, or the configurations can be partially omitted and/or modified without departing from the scope of the present disclosure.

### REFERENCE SIGNS LIST

1 heat sink; 1a heat dissipation fin; 1b heat sink base; 1bu heat sink base unevenness; 1bp outer peripheral edge; 1bs1 heat sink base's first short side; 1bs2 heat sink base's second short side; 1bl1 heat sink base's first long side; 1bl2 heat sink base's second long side; 2 fin base; 2u fin base unevenness; 3 insulating sheet; 4 wiring wire; 5 semiconductor element; 6 solder; 7 metal conductor; 8 control terminal; 9 sealing resin; 10 main terminal; 11 power module; 12 first modified heat sink; 13 second modified heat sink; 15 bonding material; 16 adhesive; 20, 21 heat sink integrated power module; 22a first protrusion; 22b second protrusion; 30 outer frame; 31 bottom surface portion; 31a inner surface; 32 side surface portion; 33 front side end; 34 back side end; 40 housing; 41 opening; 50, 51, 52 structural support; 50a, 77c screw fixing region; 50L structural support width dimension; 51a through hole; 52a irregularities; 60 holding portion; 71 housing fixing screw; 72 power module fixing screw; 73, 75 weld; 74, 76 structural support fixing screw; 77 elastic structural support; 77a1 first divided structural support; 77a2 second divided structural support; 77b coil spring; 80, 81 gap; 100, 101, 102, 103 power semiconductor device; 200 air flow; 211 first airflow vector; 212 second airflow vector; 411 opening's short side; 411a opening's first short side; 411b opening's second short side; 412 opening's long side; 412a opening's first long side; 412b opening's second long side; 413 adjacent region; 414 center region; 415 end region; 416 housing's long side.

1. A power semiconductor device comprising:
heat sink integrated power modules each including a power module and a heat sink that are integrated with each other, the heat sink including a plurality of heat dissipation fins provided on a heat sink base thereof and dissipating heat generated in the power module;
a holding portion having a box shape including an inlet of air and an outlet of air that are provided facing each other, the holding portion including one surface interconnecting the inlet and the outlet, the one surface having a plurality of openings formed thereon; and
a structural support provided inside the holding portion and supporting the one surface by bearing a load directed in a direction from the one surface toward the inside of the holding portion, wherein
the plurality of the heat dissipation fins of each of the heat sink integrated power modules is inserted in the holding portion from a corresponding one of the openings, and the heat sink base includes an outer peripheral edge supported on an adjacent region of the one surface in an in-plane direction of the heat sink base, the adjacent region being adjacent to the corresponding opening, and
the structural support is disposed extending in the direction from the inlet toward the outlet in a region from the inlet to the outlet, at a position corresponding to space between the heat sink bases of the heat sink integrated power modules adjacent to each other in a width direction of the holding portion, the width direction being a direction orthogonal to a direction from the inlet toward the outlet.

2. The power semiconductor device according to claim 1, wherein
the holding portion includes:
an outer frame having a U shape, the outer frame including a bottom surface portion and two side surface portions rising from a pair of ends of the bottom surface portion, the pair of ends facing each other; and
a plate-shaped housing constituting the one surface, the housing being supported by ends of the two side surface portions, the ends of the two side surface portions being free ends of the U shape, and
the adjacent region of the housing and the outer peripheral edge of the heat sink base are screwed together.

3. The power semiconductor device according to claim 2, wherein
the structural support is fixed to the outer frame and is in contact with the housing.

4. The power semiconductor device according to claim 2, wherein
the structural support is fixed to the housing and is in contact with the outer frame.

5. The power semiconductor device according to claim 4, wherein
the structural support has a width in the direction orthogonal to the direction from the inlet toward the outlet, and the width of the structural support is larger than a gap between the heat sink bases of the heat sink integrated power modules adjacent to each other in the width direction of the holding portion.

6. The power semiconductor device according to claim 4, comprising
a first heat sink integrated power module and a second heat sink integrated power module that are the heat sink integrated power modules adjacent to each other in the width direction of the holding portion, wherein
the first heat sink integrated power module includes a first protrusion at an end of the heat sink base on a side of the second heat sink integrated power module,
the second heat sink integrated power module includes a second protrusion at an end of the heat sink base on a side of the first heat sink integrated power module, and
the first protrusion, the second protrusion, the housing, and the structural support are screwed together overlapping one another.

7. The power semiconductor device according to claim 1, wherein
the structural support continuously extends in the direction from the inlet toward the outlet in a region from the inlet to the outlet.

8. The power semiconductor device according to claim 1, wherein
the structural support is discontinuously disposed in the direction from the inlet toward the outlet in a region from the inlet to the outlet.

9. The power semiconductor device according to claim 1, wherein
the structural support has elasticity.

10. The power semiconductor device according to claim 1, wherein
the structural support includes a through hole passing through the structural support in the direction from the inlet toward the outlet.

11. The power semiconductor device according to claim 1, wherein
the structural support includes irregularities on a surface thereof.

12. A method of manufacturing a power semiconductor device, the method comprising:
fixing a structural support to an outer frame having a U shape, the outer frame including a bottom surface portion and two side surface portions rising from a pair of ends of the bottom surface portion, the pair of ends facing each other;
placing a plate-shaped housing on ends of the two side surface portions, the ends of the two side surface portions being free ends of the U shape, the housing having a plurality of openings formed thereon;
inserting a plurality of heat dissipation fins of a heat sink integrated power module into the outer frame from a corresponding one of the plurality of the openings, and
placing an outer peripheral edge of a heat sink base in an in-plane direction of the heat sink base on an adjacent region of the housing, the adjacent region being adjacent to the corresponding opening, the heat sink integrated power module including a power module and a heat sink that are integrated with each other, the heat sink including the plurality of the heat dissipation fins provided on the heat sink base and dissipating heat generated in the power module;
screwing the housing and the outer frame together; and
screwing the outer peripheral edge of the heat sink base and the adjacent region of the housing together, wherein
the structural support is
disposed at a position corresponding to space between the heat sink bases of the heat sink integrated power modules adjacent to each other in a width direction of the U shape.

13. A method of manufacturing a power semiconductor device, the method comprising:
fixing a structural support to a plate-shaped housing having a plurality of openings formed thereon;
placing the housing on ends of two side surface portions of an outer frame having a U shape, the outer frame including a bottom surface portion and the two side surface portions rising from a pair of ends of the bottom surface portion, the pair of ends facing each other, the ends of the two side surface portions being free ends of the U shape;
inserting a plurality of heat dissipation fins of a heat sink integrated power module into the outer frame from a corresponding one of the plurality of the openings, and
placing an outer peripheral edge of a heat sink base in an in-plane direction of the heat sink base on an adjacent region of the housing, the adjacent region being adjacent to the corresponding opening in the housing, the heat sink integrated power module including a power module and a heat sink that are integrated with each other, the heat sink including the plurality of the heat dissipation fins provided on the heat sink base and dissipating heat generated in the power module;
screwing the housing and the outer frame together; and
screwing the outer peripheral edge of the heat sink base and the adjacent region of the housing together, wherein
the structural support is
disposed at a position corresponding to space between the heat sink bases of the heat sink integrated power modules adjacent to each other in a width direction of the U shape.
